(19) United States
(12) Patent Application Publication
(10) Pub. No.: US 2007/0275570 A1
(43) Pub. Date: Nov. 29, 2007

(54) Heat Treatment Apparatus

(75) Inventors: Naoto Nakamura, Toyama (JP); Iwao Nakamura, Toyama (JP); Tomoharu Shimada, Nagasaki (JP); Akira Morohashi, Tochigi (JP); Keishin Yamazaki, Toyama (JP); Sadao Nakashima, Toyama (JP)

Correspondence Address: OLIFF & BERRIDGE, PLC, P.O. BOX 19928, ALEXANDRIA, VA, 22320, US

(73) Assignee: Hitachi Kokusai Electric Inc., Tokyo (JP)

(21) Appl. No.: 10/573,025

(22) PCT Filed: Jan. 20, 2005
(86) PCT No.: PCT/JP05/00651

§ 371 Date: Jul. 20, 2006

(30) Foreign Application Priority Data
Jan. 20, 2004 (JP) 2004-012166
Mar. 25, 2004 (JP) 2004-088843

(51) Int. Cl. H01L 21/00

(52) U.S. Cl. 438/795; 432/120

(57) ABSTRACT

A heat treatment device where intervals between substrates supported by a supporter is reduced so that the number of substrates to be treated can be increased. A heat treatment device has a reaction furnace for treating substrates and a supporter for supporting the substrates in plural stages in the reaction furnace. The supporter has supporting plates in contact with the substrates and supporting members for supporting the supporting plates. A supporting plate and a supporting member are superposed on each other at least a part in the thickness direction.

### TECHNICAL FIELD

The present invention relates to a heat treatment apparatus for heat-treating semiconductor wafers or glass substrates.

### BACKGROUND ART

For example, when heat-treating a plurality of substrates such as silicon wafers using a vertical heat-treating furnace, a supporting tool (boat) formed of silicon carbide is used (see Patent Document 1). This supporting tool is provided with, for example, a supporting strip for supporting the substrate at three points.

Patent Document 1: JP-A-7-45691

In this case, there is a problem such that when the heat treating is performed at a temperature exceeding 1000° C., a slip dislocation occurs on the substrate, near the supporting strip, which results in generation of a slip line. When the slip line is generated, flatness of the substrate is deteriorated. This is lead to a problem such that displacement of mask alignment (displacement of mask alignment due to displacement or deformation of focal point) occurs in a lithography step, which is one of the most important steps in an LSI manufacturing process, and hence it is difficult to manufacture an LSI having a desired pattern.

### DISCLOSURE OF THE INVENTION

### PROBLEMS TO BE SOLVED BY THE INVENTION

As means for solving the problems, a method of placing a supporting plate on a supporting strip, and placing a substrate to be treated on the supporting plate is considered.

FIG. 25 and FIG. 26 show an example of a supporting tool 30 of this type.

The supporting tool 30 includes three supporting strips 66 which are formed at a position apart from each other by, for example, 90°, and a supporting plate 58 is supported by the supporting strips 66. A number of the sets of the supporting strips 66 are provided at predetermined intervals in a vertical direction, and the supporting plates 58 are supported by the sets of the supporting strips 66. The supporting plate 58 is formed, for example, of silicon (Si), and a diameter of the supporting plate 58 is smaller than a substrate 72. Since the supporting plate 58 is formed of the same material as the silicon substrate 72, the coefficient of thermal expansion is the same, and hence it has an advantage such that slippage of the substrate 72 does not occur.

In order to make the substrate 72 supported by the supporting tool 30, as shown in FIG. 26, the substrate 72 is placed on the supporting plate 58 by moving tweezers 32 on which the substrate 72 is placed to a position above the supporting plate 58, and then moving the same to a position lower than an upper surface of the supporting plate 58.

Since a very long process time is required for a high-temperature processing, a batch processing of a large amount is desired when the throughput is considered. Increase in number of substrates to be processed per batch processing leads to improvement of the throughput. In order to increase the number of substrate to be processed, either one of increasing a processing area (flat zone length) or reducing an inter-substrate pitch is to be selected. Since increasing of the processing area (flat zone length) results in upsizing of a substrate processing apparatus, the reduction of inter-substrate pitch is advantageous from this point.

As will be understood in FIG. 26, the left and right supporting strips 66, 66 of the supporting tool 30 are located at interfering positions due to vertical movement of the tweezers 32. Assuming that al represents the thickness of the substrate+a vertical clearance when being inserted, b1 represents the thickness of the tweezers+a vertical clearance when the tweezers are moved down, and c1 represents the thickness of the supporting strips 66, 66, the inter-substrate pitch P1 is represented by a1+b1+c1. In other words, a1 designates a distance between the upper surface of the supporting plate 58 and lower surfaces of the supporting strips 66, 66 located above, and b1 designates the thickness of the supporting plate 58.

In this case, it is necessary to secure a distance to an extent that can avoid interference between the tweezers 32 and the supporting strip 66 when the tweezers 32 are moved downward, and to set the thickness (b1) of the supporting plate 58 to at least 6.5 mm. Assuming that the thickness (c1) of the supporting strip 66 is, for example, 3 mm, an the clearance (a1) for moving the substrate 72 in the vertical direction is 4 mm, a total pitch (P1) of 13.5 mm is required.

Although it is considered to reduce the thickness (c1) of the supporting strips 66, 66 in order to reduce the inter-substrate pitch, it is not possible to reduce the thickness easily from the view point of strength.

It is an object of the present invention to provide a heat treatment apparatus in which an inter-substrate pitch is reduced, the number of substrates to be processed per batch is increased, and hence the high-throughput is achieved.

### MEANS FOR SOLVING THE PROBLEM

In order to solve the above-described problem, a first characteristic of the present invention is a heat treatment apparatus including a reactor for treating substrates, and a supporting tool for supporting a plurality of the substrates in a plurality of stages in the reactor, wherein the supporting tool includes a plurality of supporting plates that come into contact with the plurality of substrates respectively, and a plurality of supporting strips for supporting the plurality of supporting plates in the plurality of stages, and the supporting plates and the supporting strips overlap at least partly in a direction of the thickness. Recesses may be formed on either one of back surfaces of the supporting plates or on upper surfaces of the supporting strips. Alternatively, the recesses may be formed on the upper surfaces of the supporting strips that come into contact with the back surfaces of the supporting plates.

A second characteristic of the present invention is a heat treatment apparatus including a reactor for treating substrates, and a supporting tool for supporting a plurality of the substrates in a plurality of stages in the reactor, wherein the supporting tool includes a plurality of supporting plates that come into contact with the plurality of substrates respectively, a plurality of supporting strips for supporting the plurality of supporting plates in the plurality of stages, the supporting plates and the supporting strips overlap at least partly in a direction of the thickness, and a substrate transfer unit for putting the substrates to the supporting tool, wherein the substrate transfer unit includes tweezers for putting the substrates, and wherein the supporting strips are formed with recesses on the upper surfaces thereof at portions that oppose the tweezers at least when transferring the substrates. It is also possible to provide the recesses on the supporting strips at least in a range from the portions that opposes the tweezers when transferring the substrates to ends on a side where the supporting plates are supported.

The third characteristic of the present invention is a heat treatment apparatus including a reactor for treating substrates, and a supporting tool for supporting a plurality of the substrates in a plurality of stages in the reactor, wherein the supporting tool includes a plurality of supporting plates that come into contact with the plurality of substrates respectively, and a plurality of supporting strips for supporting the plurality of supporting plates in the plurality of stages, and wherein fitting portions for achieving mutual fitting are provided at least on one of the supporting plates and the supporting strips.

A fourth characteristic of the present invention is a heat treatment apparatus including a reactor for treating substrates, and a supporting tool for supporting a plurality of the substrates in a plurality of stages in the reactor, wherein the supporting tool includes a plurality of supporting plates that come into contact with the plurality of substrates respectively, and a plurality of supporting strips for supporting the plurality of supporting plates in the plurality of stages, the supporting strips are configured to support at least outer peripheral portions of the supporting plates on a substrate insertion side.

A fifth characteristic of the present invention is a heat treatment apparatus including a reactor for treating substrates, and a supporting tool for supporting a plurality of the substrates in a plurality of stages in the reactor, wherein the supporting tool includes a plurality of supporting plates that come into contact with the plurality of substrates respectively, and a plurality of supporting strips for supporting the plurality of supporting plates in the plurality of stages, the supporting strip has a skeleton structure, wherein the supporting plate includes at least one through hole, the supporting strips are configured so as not to overlap the at least one through hole. It is also possible to provide one through hole at a center of the supporting plate, and adapt the supporting strips to support an outer portion of the through hole.

The sixth characteristic of the present invention is a heat treatment apparatus including a reactor for treating substrates, and a supporting tool for supporting a plurality of the substrates in a plurality of stages in the reactor, wherein the supporting tool includes a plurality of supporting plates that come into contact with the plurality of substrates respectively, and a plurality of supporting strips for supporting the plurality of supporting plates in the plurality of stages, wherein the supporting plates and the supporting strips overlap at least partly in a direction of the thickness, wherein the supporting tool further includes a plurality of pillars, the supporting strips are formed integrally with the pillars so as to connect the plurality of pillars, and the supporting strips and the pillars are formed of SiC impregnated with Si.

A seventh characteristic of the present invention is a method of manufacturing a substrate including a step of supporting a plurality of the substrates in a plurality of stages with a supporting tool including a plurality of supporting plates that come into contact with the plurality of substrates respectively and a plurality of supporting strips for supporting the plurality of supporting plates in the plurality of stages and being configured in such a manner that the supporting plates and the supporting strips overlap at least partly in a direction of thickness, a step of carrying the plurality of substrates supported by the supporting tool into a reactor; a step of heat-treating the plurality of substrates supported by the supporting tool in the reactor, and a step of carrying out the plurality of substrates supported by the supporting tool from the reactor after having heat-treated.

Preferably, the heat treatment apparatus includes the reactor for treating the substrate, the supporting tool for supporting the substrates in the reactor, and the substrate transfer unit having the tweezers for placing the substrate thereon for transferring the substrate to the supporting tool, the supporting tool includes the supporting plates that come into contact with the substrates and the supporting strips for supporting the supporting plates, and the recesses corresponding to the tweezers are formed on the upper surfaces of the supporting strips.

Preferably, the supporting strips are formed so as to extend from a supporting tool body horizontally and are formed with the recesses so as to be thick at root portions on a side of the supporting tool body and to be thin at distal end portions.

Preferably, the heat treatment apparatus includes the reactor for treating the substrates, the supporting tool for supporting the substrate in the reactor, and the substrate transfer unit having the tweezers for placing the substrate thereon and transferring the substrate to the supporting tool, the supporting tool includes the supporting plates that come into contact with the substrates and the supporting strips for supporting the supporting plates, and the supporting strip is formed into a shape that allows insertion of the tweezers with respect to the supporting tool within a range including at least part of the thickness of the supporting strip.

Preferably, the supporting strips include projections projecting toward a tweezers insertion side. The shape having the projection includes, for example, an M-shape or a U-shape in lateral cross-section. When it is formed into the U-shape, the supporting strip may be configured to be supported on a side opposite from the tweezers insertion side, and to support the supporting plate by a curved portion at the distal end thereof. In this case, preferably, engaging groove is formed on the outer peripheral portion of the supporting plate, and the supporting strip is fitted into the engaging groove. When the supporting plate is formed into a disk-shape, preferably, the width of the supporting strip is equal to or smaller than a diameter of the supporting plate. The supporting strip is preferably formed of silicon carbide (SiC) or SiC impregnated with silicon (Si).

Preferably, the tweezers include an opening that surrounds the projection of the supporting strip. The shape having the opening includes the shape of substantially the U-shape. When the supporting strip is formed into the M-shape, preferably, the distal ends of the tweezers are cut out so as to match the supporting strip.

Preferably, the supporting plate is formed into a disk-shape having a diameter smaller than the substrate. Preferably, the supporting plate is formed of silicon (Si). When the substrate is formed of silicon, the substrate and the supporting plate are formed of the same material. Therefore, they have the same coefficient of thermal expansion, and hence occurrence of slippage of the substrate caused by difference in coefficient of thermal expansion can be prevented.

Preferably, the plurality of supporting strips and supporting plates are provided and the supporting tool is formed so as to support the plurality of substrates in a substantially horizontal state in a plurality of stages with clearances therebetween.

Preferably, the heat treatment of the present invention is performed at high-temperatures higher than 1000° C., higher than 1200° C., and higher than 1350° C.

### BRIEF DESCRIPTION OF THE DRAWINGS

FIG. 1 is a perspective view showing a substrate processing apparatus according to an embodiment of the present invention.

FIG. 2 is a drawing showing a reactor used for the substrate processing apparatus according to the embodiment of the present invention.

FIG. 3 shows a supporting tool according to a first embodiment of the present invention, wherein (a) is a side view, and (b) is a lateral cross-sectional view.

FIG. 4 shows the supporting tool according to the first embodiment of the present invention, wherein (a) is a vertical cross-sectional view, and (b) is a perspective view showing a supporting strip and a supporting plate.

FIG. 5 shows a first modification of the supporting tool according to the first embodiment of the present invention, wherein (a) is a lateral cross-sectional view, (b) is a cross-sectional view taken along the line A-A in the drawing (a), and (c) is a cross-sectional view taken along the line B-B in the drawing (a).

FIG. 6 shows a second modification of the supporting tool according to the first embodiment of the present invention, wherein (a) is a lateral cross-sectional view, (b) is a side view, (c) is a cross-sectional view taken along the line C-C in the drawing (a).

FIG. 7 shows a third modification of the supporting tool according to the first embodiment of the present invention, wherein (a) is a lateral cross-sectional view, (b) is a side view, and (c) is a cross-sectional view taken along the line D-D in the drawing (a).

FIG. 8 shows a fourth modification of the supporting tool according to the first embodiment of the present invention, wherein (a) is a lateral cross-sectional view, (b) is a cross-sectional view taken along the line E-E in the drawing (a), and (c) is a cross-sectional view taken along the line F-F in the drawing (a).

FIG. 9 shows a fifth modification of the supporting tool according to the first embodiment of the present invention, wherein (a) is a lateral cross-sectional view, (b) is a cross-sectional view taken along the line G-G in the drawing (a), and (c) is a cross-sectional view taken along the line H-H in the drawing (a).

FIG. 10 shows a sixth modification of the supporting tool according to the first embodiment of the present invention, wherein (a) is a lateral cross-sectional view, (b) is a cross-sectional view taken along the line I-I in (a), and (c) is a cross-sectional view taken along the line J-J in the drawing (a).

FIG. 11 shows a perspective view showing the supporting tool according to a second embodiment of the present invention.

FIG. 12 shows the supporting tool according to the second embodiment of the present invention, wherein (a) is a lateral cross-sectional view, (b) is a cross-sectional view taken along the line K-K in the drawing (a), and (c) is a cross-sectional view taken along the line L-L in the drawing (a).

FIG. 13 shows a first modification of the supporting tool according to the second embodiment of the present invention, wherein (a) is a lateral cross-sectional view, (b) is a cross-sectional view taken along the line M-M in the drawing (a), and (c) is a cross-sectional view taken along the line N-N in the drawing (a).

FIG. 14 shows a second modification of the supporting tool according to the second embodiment of the present invention, wherein (a) is a lateral cross-sectional view, (b) is a cross-sectional view taken along the line O-O in the drawing (a), and (c) is a cross-sectional view taken along the line P-P in the drawing (a).

FIG. 15 shows a third modification of the supporting tool according to the second embodiment of the present invention, wherein (a) is a lateral cross-sectional view, (b) is a cross-sectional view taken along the line Q-Q in the drawing (a), and (c) is a cross-sectional view taken along the line R-R in the drawing (a).

FIG. 16 is a perspective view showing the supporting tool according to a third embodiment of the present invention.

FIG. 17 shows the supporting tool according to the third embodiment of the present invention, wherein (a) is a lateral cross-sectional view, and (b) is a cross-sectional view taken along the line S-S in the drawing (a).

FIG. 18 shows the supporting tool according to the third embodiment of the present invention, wherein (a) is a vertical cross-sectional view when tweezers are inserted, and (b) is a vertical cross-sectional view when the tweezers are moved downward.

FIG. 19 shows a procedure for causing the supporting tool to support a substrate in the third embodiment of the present invention, wherein (a) to (d) are vertical cross-sectional views showing a relation between the supporting tool and the tweezers in the respective steps.

FIG. 20 shows a first modification of the supporting tool according to the third embodiment of the present invention, wherein (a) is a lateral cross-sectional view, and (b) is a cross-sectional view taken along the line S-S in the drawing (a).

FIG. 21 shows a second modification of the supporting tool according to the third embodiment of the present invention, wherein (a) is a lateral cross-sectional view, and (b) is a cross-sectional view taken along the line T-T in the drawing (a).

FIG. 22 shows a third modification of the supporting tool according to the third embodiment of the present invention, wherein (a) is a lateral cross-sectional view, and (b) is a cross-sectional view taken along the line U-U in the drawing (a).

FIG. 23 shows a fourth modification of the supporting tool according to the third embodiment of the present invention, wherein (a) is a lateral cross-sectional view, and (b) is a cross-sectional view taken along the line V-V in the drawing (a).

FIG. 24 shows a fifth modification of the supporting tool according to the third embodiment of the present invention, wherein (a) is a lateral cross-sectional view, and (b) is a cross-sectional view taken along the line W-W in the drawing (a).

FIG. 25 shows a supporting tool in a substrate processing apparatus in the related art, wherein (a) is a lateral cross-sectional view, and (b) is a front view.

FIG. 26 shows the supporting tool in the substrate processing apparatus in the related art, wherein (a) is a vertical cross-sectional view when tweezers are inserted, and (b) is a vertical cross-sectional view when the tweezers are moved downward.

FIG. 27 shows the supporting tool in the substrate processing apparatus in the related art, wherein (a) is a lateral cross-sectional when the tweezers are inserted, and (b) is a vertical cross-sectional view when the tweezers are moved downward.

### REFERENCE NUMERALS

10 heat treatment apparatus
26 substrate transfer unit
30 supporting tool
32 tweezers
40 reactor
58 supporting plate
64 pillar
66 supporting strip
72 substrate
78 engaging groove (fitting portion)
84 through hole
88 recess

### BEST MODE FOR CARRYING OUT THE INVENTION

Referring now to the drawings, embodiments of the present invention will be described.

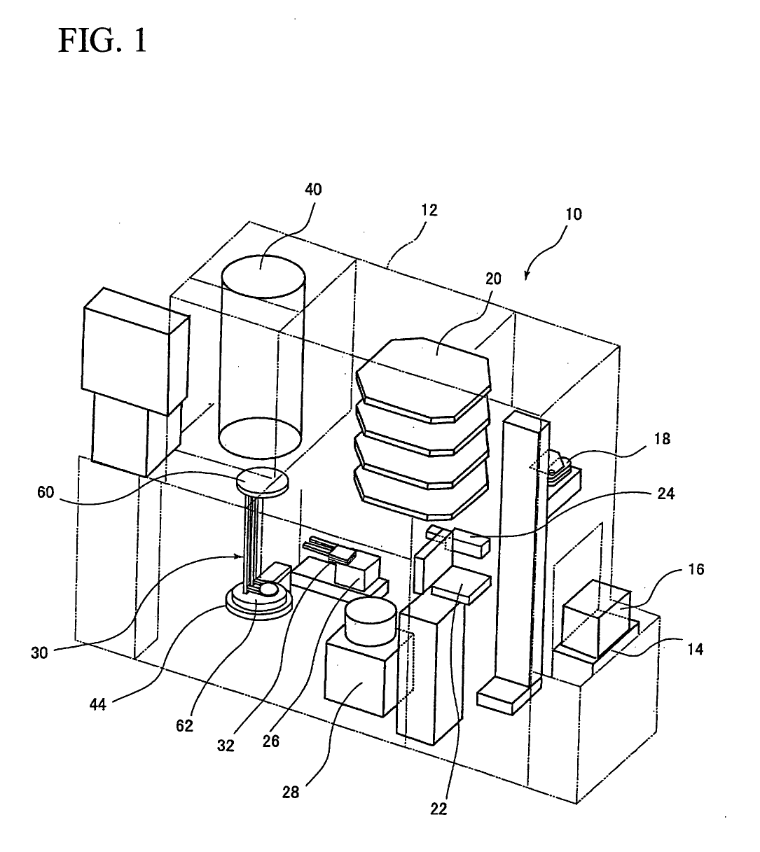

FIG. 1 shows a heat treatment apparatus 10 according to the present invention. This heat treatment apparatus 10 is, for example, a vertical type, and includes an enclosure 12 in which a principal portion is arranged. The enclosure 12 is connected to a pod stage 14 and a pod 16 is transported to the pod stage 14. The pod 16 accommodates, for example, 25 substrates, and is set in the pod stage 14 in a state of being closed by a lid, not shown.

A pod transporting device 18 is arranged at a position opposing to the pod stage 14 in the enclosure 12. A pod shelf 20, a pod opener 22, and a substrate number detector 24 are arranged in the vicinity of the pod transporting device 18. The pod transporting device 18 transports the pod 16 among the pod stage 14, the pod shelf 20 and the pod opener 22. The pod opener 22 is for opening the lid of the pod 16, and the number of the substrates in the pod 16 whose lid is opened is detected by the substrate number detector 24.

Furthermore, a substrate transfer unit 26, a notch aligner 28, and a supporting tool 30 (boat) are arranged in the enclosure 12. The substrate transfer unit 26 includes tweezers 32 that can take out, for example, five substrates, and the substrates are transported among the pod, the notch aligner 28, and the supporting tool 30 located at the pod opener 22 by moving the tweezers 32. The notch aligner 28 detects a notch or an orientation flat formed on the substrate to align the notch or the orientation flat on the substrate at a certain position.

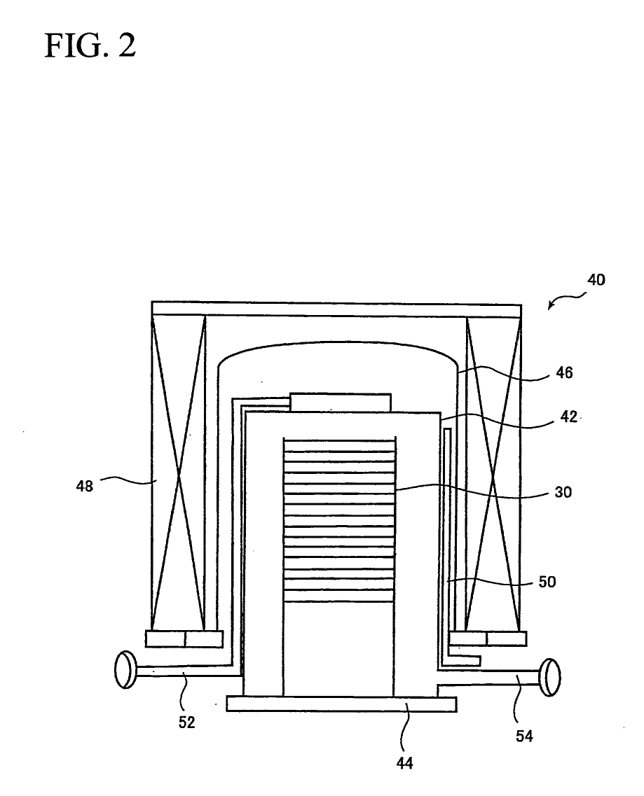

A reactor 40 is shown in FIG. 2. The reactor 40 has a reaction tube 42, and the supporting tool 30 is inserted in the reaction tube 42. The reaction tube 42 is opened on a lower side so that the supporting tool 30 can be inserted, and an opened portion thereof is configured to be sealed by a seal cap 44. The reaction tube 42 is covered by a liner tube 46 therearound, and a heater 48 is arranged around the liner tube 46. A thermoelectric couple 50 is arranged between the reaction tube 42 and the liner tube 46, so that the temperature in the reactor 40 can be monitored. An introduction tube 52 for introducing processing gas and an exhaust tube 54 for exhausting processing gas are connected to the reaction tube 42.

Subsequently, an operation of the heat treatment apparatus 10 configured as described above will be described.

When the pod 16 including the plurality of substrates stored therein is set to the pod stage 14, the pod 16 is transported from the pod stage 14 to the pod shelf 20 by the pod transporting device 18, and is stored in the pod shelf 20. Subsequently, the pod 16 stored in the pod shelf 20 is transported to the pod opener 22 and set thereto, where the lid of the pod 16 is opened by the pod opener 22, and then the number of substrates stored in the pod 16 is detected by the substrate number detector 24.

Subsequently, the substrates are taken out from the pod 16 at a position of the pod opener 22 by the substrate transfer unit 26, and are transferred to the notch aligner 28. In this notch aligner 28, the notch is detected while rotating the substrate, and the notches of the plurality of substrates are aligned at the same position on the basis of detected information. Subsequently, the substrates are taken out from the notch aligner 28 by the substrate transfer unit 26 and transferred to the supporting tool 30.

When the substrates corresponding to one batch are transferred to the supporting tool 30 in this manner, the supporting tool 30 including the plurality of substrates charged therein is put in the reactor 40 set to a temperature, for example, on the order of 700° C., and the reaction tube 42 is sealed by the seal cap 44. Subsequently, the temperature in the reactor is increased to a heat treatment temperature to introduce processing gas from the introduction tube 52. The processing gas includes nitrogen, argon, hydrogen, oxygen, and so on. When heat-treating the substrates, the substrates are heated to a temperature, for example, higher than 1000° C. During this time, the heat treatment of the substrates is performed according to a predetermined temperature-rise, heat treatment program while monitoring the temperature in the reaction tube 42 by the thermoelectric couple 50.

When the heat treatment of the substrates is ended, for example, after having lowered the temperature in the reactor to a temperature on the order of 700° C., the supporting tool 30 is unloaded from the reactor 40, and is kept on stand-to at a predetermined position until all the substrates supported in the supporting tool 30 are cooled. Lowering of the temperature in the reactor is also performed according to a predetermined temperature-down program while monitoring the temperature in the reaction tube 42 by the thermoelectric couple 50. Subsequently, when the substrates in the supporting tool 30 kept on stand-to are cooled to the predetermined temperature, the substrates are taken out from the supporting tool 30 by the substrate transfer unit 26, and are transported to and stored in a vacant pod 16 set to the pod opener 22. Subsequently the pod 16 including the substrates stored therein is transported by the pod transporting device 18 to the pod shelf 20, and is further transported to the pod stage 14 to complete the procedure.

Subsequently, the supporting tool 30 described above will be described.

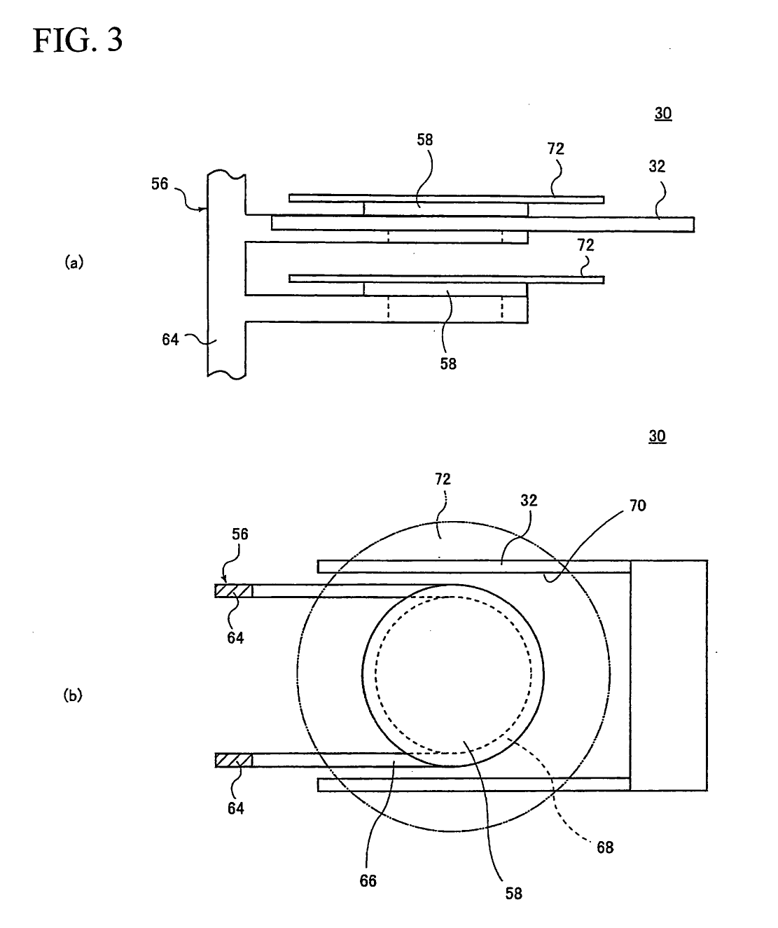

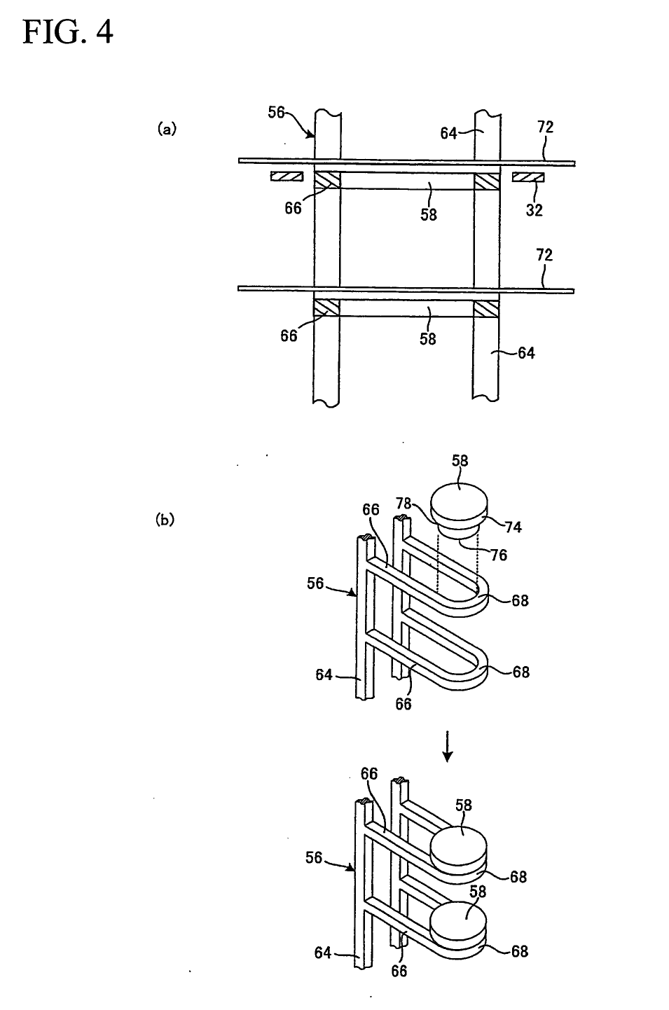

FIG. 3 and FIG. 4 show a first embodiment, the supporting tool 30 includes a body portion 56 and supporting plates 58. The body portion 56 is formed of silicon carbide or silicon carbide (SiC) impregnated with silicon (Si), and includes an upper plate 60 (shown in FIG. 1) of a disk-shape, a lower plate 62 (shown in FIG. 1) also of the disk-shape, a plurality of, two for example, pillars 64, 64 for connecting the upper plate 60 and the lower plate 62, and supporting strips 66 that connect the pillars 64, 64. The supporting strips 66 are formed integrally with the pillars 64, 64 so as to connect the two pillars 64, 64, and the supporting strips 66 and the pillars 64, 64 are formed into a skeleton (framework) structure. The supporting strip 66 is formed, for example, into an U-shape from above, and extends in the horizontal direction, and includes a projection 68 which projects toward a tweezers 32 insertion side, descried later (the side of the substrate transfer unit 26). A number of the supporting strips 66 are formed in a vertical direction with respect to the pillars 64 at regular intervals, and the supporting plates 58 are supported by the plurality of supporting strips 66 respectively. Substrates 72 are supported so that lower surfaces of the substrates 72 come into contact with upper surfaces of the supporting plates 58. The supporting strips 66 and the pillars 64 are integrally formed by cutting out a pillar-shaped member so as to leave portions that correspond to the supporting strips 66 and the pillars 64.

The supporting plate 58 is formed, for example, of silicon into the disk-shape. The width of the entirety of the supporting strip 66 is equal to or smaller than a diameter of the supporting plate 58. The supporting plate 58 has a thin peripheral portion (outer peripheral portion) 74 and a thick central portion 76, and an engaging groove 78 (fitting portion) in a shape of a recess is formed on a lower portion (back surface) of the peripheral portion 74. In other words, a projection is formed at the center portion 76 on the back surface of the supporting plate 58, and a recess is formed on the peripheral portion 74 of the supporting plate 58.

The projection 68 of the supporting strip 66 is formed into a semi-circular shape when viewed from above, and the engaging groove 78 of the supporting plate 58 is fitted to the projection 68 of the supporting strip 66, whereby the supporting plate 58 is supported by the supporting strip 66. In other words, the supporting plate 58 and the supporting strip 66 are formed with fitting portion (the engaging groove 78 of the supporting plate 58 and the projection 68 of the supporting strip 66) for mutual (supporting plate 58 and the supporting strip 66) fitting, so that the supporting plate 58 and the supporting strip 66 are overlapped with each other partly (the center portion 76 of the supporting plate 58 and the supporting strip 66) in the direction of thickness. The supporting strip 66 supports portion more than half an outer peripheral portion of the supporting plate 58 on a substrate insertion side.

In this manner, with the structure in which the supporting plate 58 and the supporting strip 66 are overlapped at least partly in the direction of the thickness, that is, with the structure in which the center portion 76 of the supporting plate 58 and the width (height) of the supporting strip 66 are overlapped in the direction of the thickness, the total thickness of the supporting plate 58 and the supporting strip 66 in a state in which the supporting plate 58 is supported by the supporting strip 66 can be reduced, whereby the inter-substrate pitch can be reduced.

As described above, since the supporting plate 58 and the supporting strip 66 are provided with the fitting portion to achieve the mutual fitting, positioning of the supporting plate 66 is enabled, and displacement of the supporting plate 66 and drop off of the supporting plate 66 can be prevented. For example, when a force in a direction opposite from a direction of insertion of the substrate is applied to the supporting plate 58, the supporting plate 58 can be prevented from moving (displacing) to the side opposite from the pillar 64.

As described above, the supporting tool 30 includes the plurality of pillars 64 and the supporting strips 66, the supporting strips 66 are formed integrally with the pillars 64 so as to connect the plurality of pillars 64. By forming the supporting strips 66 and the pillars 64 of SiC impregnated with Si, the pillars 64 and the supporting strips 66 out of the body portion 56 formed of SiC impregnated with Si can be manufactured as a unit while maintaining the strength thereof.

As described above, with the structure in which the outer peripheral portion of the supporting plate 58 on the substrate insertion side is supported by the supporting strips 66 of the skeleton (framework) structure, lifting of the supporting plate 58 when placing the substrate can be prevented.

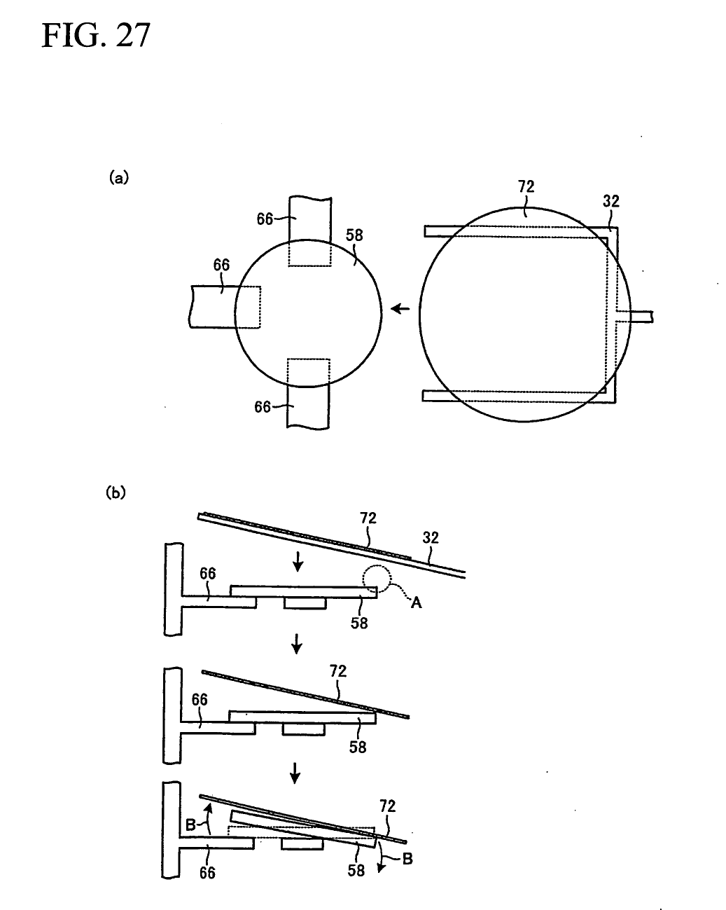

In other words, as shown in FIGS. 27(a), (b), in the case in which the supporting plate 58 is supported at three points for example, the supporting plate 58 may be lifted with respect to the supporting strip 66 when the substrate 72 is placed on the supporting plate 58. For example, when the substrate 72 is already in abutment with an upper portion of the supporting plate 58 on the substrate insertion side (a portion indicated by a broken line A in FIG. 27(b)) (when the substrate 72 is inclined), the supporting plate 58 rotates in a direction indicated by an arrow B, and is lifted with respect to the supporting strip 66. When the supporting plate 58 is lifted as described above, or when the lifted supporting plate 58 is returned to its original position, the supporting strip 66 and the supporting plate 58 come into friction, and hence particles (foreign substances) may be generated, or the supporting plate 58 may be displaced with respect to the supporting strip 66.

On the other hand, in this embodiment, since the outer peripheral portion of the supporting plate 58 of at least on the substrate insertion side is supported by the supporting strip 66 of the skeleton (framework) structure, even when the substrate 72 is already in abutment with the upper portion of the supporting plate 58 in the substrate insertion side (the distal end side of the projection 68) when the substrate 72 is placed on the supporting plate 58, the supporting plate 58 is prevented from being lifted with respect to the supporting strip 66. Therefore, displacement of the supporting plate 58 with respect to the supporting strip 66 and generation of particles (foreign substances) due to frictional contact between the supporting strip 66 and the supporting plate 58 can be prevented.

The shape of the supporting plate 58 does not have to be the disk-shape as in this embodiment, and may be an oval or polygonal plate member when viewed from above. The shape of the supporting strip 66 can be changed according to the shape of the supporting plate 58. The supporting plate 58 can be fixed to the supporting strip 66.

The diameter of the supporting plate 58 is smaller than a diameter of the substrate 72, that is, the upper surface of the supporting plate 58 has a smaller surface area than a surface area of a flat surface, which is the lower surface of the substrate 72, and the substrate 72 is supported by the supporting plate 58 over a range except for a peripheral edge thereof. The substrate 72 has a diameter of, for example, 300 mm, and hence the diameter of the supporting plate 58 is smaller than 300 mm, and preferably, is on the order of 100 mm to 250 mm (on the order of ⅓ to ⅚ of the outer diameter of the substrate). The thickness of the supporting plate 58 is set to a thickness larger than that of the substrate 72.

An adhesion preventing layer can be formed on the upper surface of the supporting plate 58. The adhesion preventing layer is formed of a material superior in heat-resistance and abrasion resistance such as a silicon nitride film (SiN), a silicon carbide film (SiC), a silicon oxide film (SiO2), a vitrified carbon, crystallite diamond formed, for example, by treating the silicon surface, or by deposition on the silicon surface by CVD or the like, so that adhesion between the supporting plate 58 and the substrate 72 after processing the substrate 72 is prevented. When the adhesion preventing layer is formed of a film of silicon carbide, the thickness of the film is preferable from 0.1 μm to 50 μm. When the film of silicon carbide is too thick, the supporting plate 58 formed of silicon is pulled by the film of silicon carbide due to the difference of the coefficient of thermal expansion between the silicon and silicon carbide and hence the amount of deformation of the supporting plate as a whole is increased, which may cause slippage of the substrate 72. In contrast, when the thickness of the film formed of silicon carbide in the range described above is employed, the extent of the supporting plate 58 formed of silicon being pulled by the film formed of silicon carbide is reduced, and hence the amount of deformation of the supporting plate as a whole is also reduced. In other words, when the thickness of the film formed of silicon carbide is reduced, a stress caused by the difference of the coefficient of thermal expansion between the supporting plate 58 and the film is reduced, and hence the amount of deformation of the supporting plate as a whole is also reduced, so that the coefficient of thermal expansion of the supporting plate as a whole becomes closer to the original coefficient of thermal expansion of the silicon (substantially the same coefficient of thermal expansion when the substrate is formed of silicon), whereby occurrence of slippage can be prevented.

In the above described embodiment, since the thickness of the supporting plate 58 is set to the predetermined thickness which is larger than the thickness of the substrate 72 as described above, rigidity of the supporting plate 58 can be increased, and hence deformation of the supporting plate 58 due to the change in temperature at the time of carrying in of the substrate, at the time of increase or decrease of temperature, at the time of heat-treating substrate, and at the time of carrying out of the substrate can be constrained. Accordingly, occurrence of slippage of the substrate 72 caused by deformation of the supporting plate 58 can be prevented. Since the material employed for the supporting plate 58 is silicon which is the same material as the substrate 72, that is, the material which has the same coefficient of thermal expansion or the hardness as the substrate 72 formed of silicon, the difference in thermal expansion and thermal contraction between the substrate 72 and the supporting plate 58 with respect to the temperature change can be eliminated. Even when a stress is generated at a contact point between the substrate 72 and the supporting plate 58, the stress can easily be released, and hence the substrate 72 can hardly be damaged. Consequently, occurrence of slippage of the substrate 72 caused by the difference in coefficient of thermal expansion and hardness between the substrate 72 and the supporting plate 58 can be prevented.

In the description of the embodiment and the example above, the case in which the diameter (surface area) of the supporting plate is smaller than that of the substrate has been described. However, the diameter of the supporting plate can be set to a larger diameter than that of the substrate. In this case, in order to secure rigidity of the supporting plate 58, the thickness of the supporting plate 58 must be increased.

The tweezers 32 of the substrate transfer unit 26 described above are formed substantially into the U-shape, and have an opening 70. The width of an inside of the opening 70 is larger than the width of an outside of the supporting strip 66, and the tweezers 32 are configured to be inserted into the supporting tool 30 within a range including part of the thickness of the supporting strip 66. In other words, as shown in FIG. 3(b), in a state in which the tweezers 32 are inserted into the supporting tool 30 to place the substrate 72 on the supporting tool, a projection plane obtained by projecting the supporting strip 66 in a direction of the plane thereof does not overlap with a projection plane obtained by projecting the tweezers 32 in a direction of the plane. Therefore, since the tweezers 32 can be inserted within the range including the thickness of the supporting strip 66 to place the substrate 72 on the supporting tool 30 and take out the same from the supporting tool 30, the inter-substrate pitch can be reduced correspondingly.

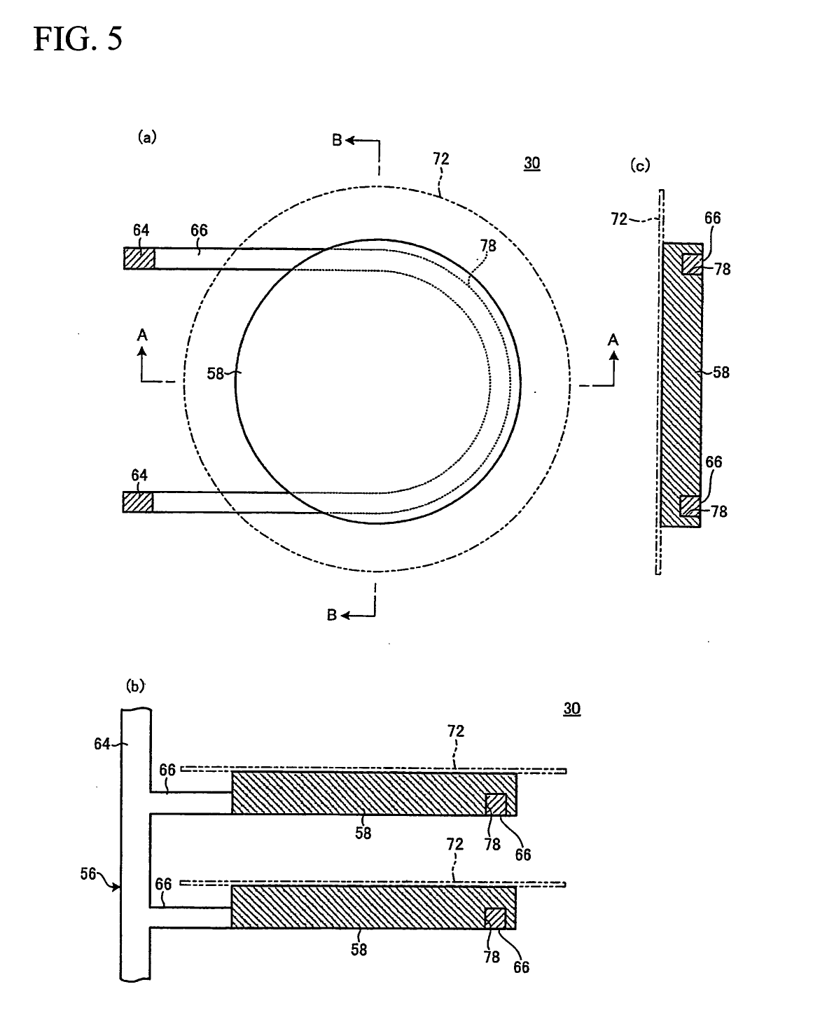

FIG. 5 shows a first modification of the first embodiment.

The first modification is different from the first embodiment described above in the shape of the supporting plate 58. In other words, the diameter of the supporting plate 58 is larger than the width of the supporting strip 66, and the engaging groove 78 (fitting portion) in a shape of a recess is provided on a lower portion (back surface) of the supporting plate 58. The engaging groove 78 is formed into a U-shape so as to match the shape of the supporting strip 66 of the supporting tool 30, and the engaging groove 78 is fitted to the supporting strip 66 so that the supporting plate 58 is supported by the supporting strip 66.

By a mutual fitting between the supporting strip 66 and the engaging groove 78 of the supporting plate 58, movement (displacement) of the supporting plate 58 horizontally with respect to the supporting strip 66 can be prevented. For example, even when a force in the direction of insertion of the substrate is applied to the supporting plate 58, movement (displacement) of the supporting plate 58 in the direction of the pillar 64 of the supporting tool 30 (a side of a root of the supporting strip 66) can be prevented.

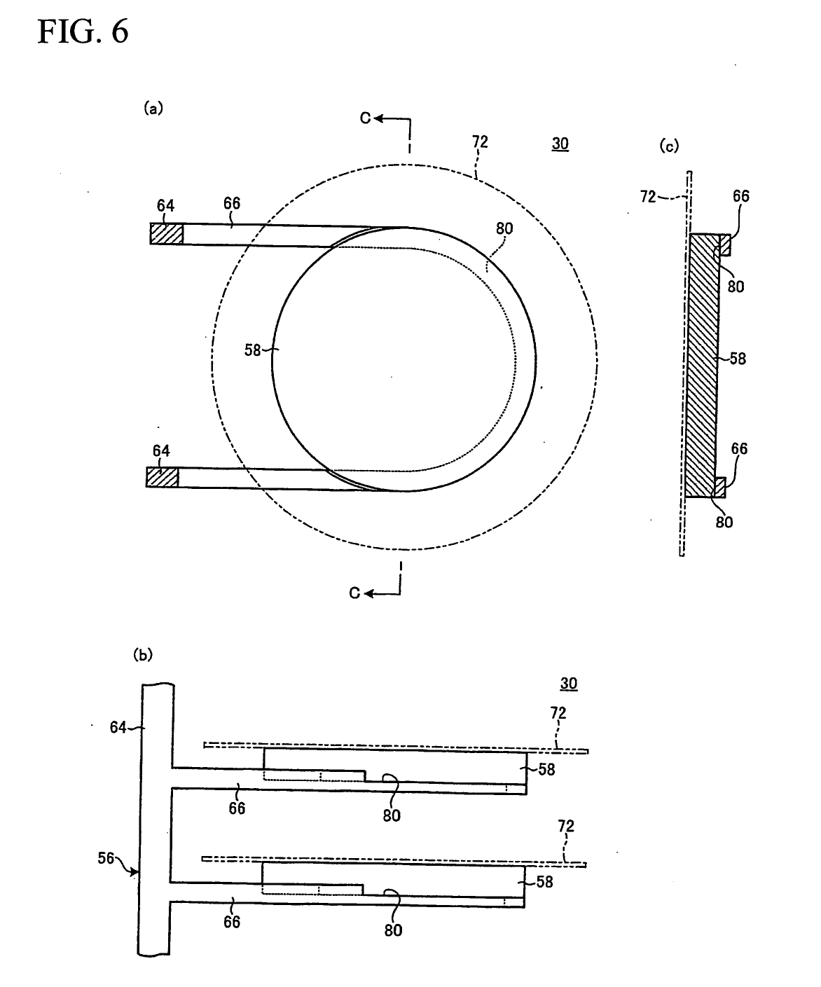

FIG. 6 shows a second modification of the first embodiment.

The second modification is different from the first embodiment described above in the shapes of the supporting strip 66 and the supporting plate 58.

A groove 80 (fitting portion) as a recess is formed on an upper surface of the supporting strip 66 in the vicinity of the substrate insertion side, and the width of the supporting strip 66 is equal to or smaller than the diameter of the supporting plate 58. The supporting plate 58 is formed into a simple disk-shape having no projection and depression on the lower portion (back surface). The groove 80 of the supporting strip 66 is formed into a circular shape when viewed from above so as to match the shape of the supporting plate 58, and the outer peripheral portion of the lower portion (back surface) of the supporting plate 58 comes into contact with the groove 80 of the supporting strip 66 so that the outer peripheral portion of the supporting plate 58 is supported by the supporting strip 66.

By the supporting plate 58 being supported by the groove 80 of the supporting strip 66 as described above, movement (displacement) of the supporting plate 58 in the direction toward the pillar 64 of the supporting tool 30 (toward the side of the root of the supporting strip 66) with respect to the supporting strip 66 can be prevented. In other words, even when a force in the direction of insertion of the substrate is applied to the supporting plate 58, the outer peripheral surface (end surface) of the supporting plate 58 comes into abutment with a side wall of the groove 80 of the supporting strip 66, so that movement (displacement) of the supporting plate 58 with respect to the supporting strip 66 can be prevented.

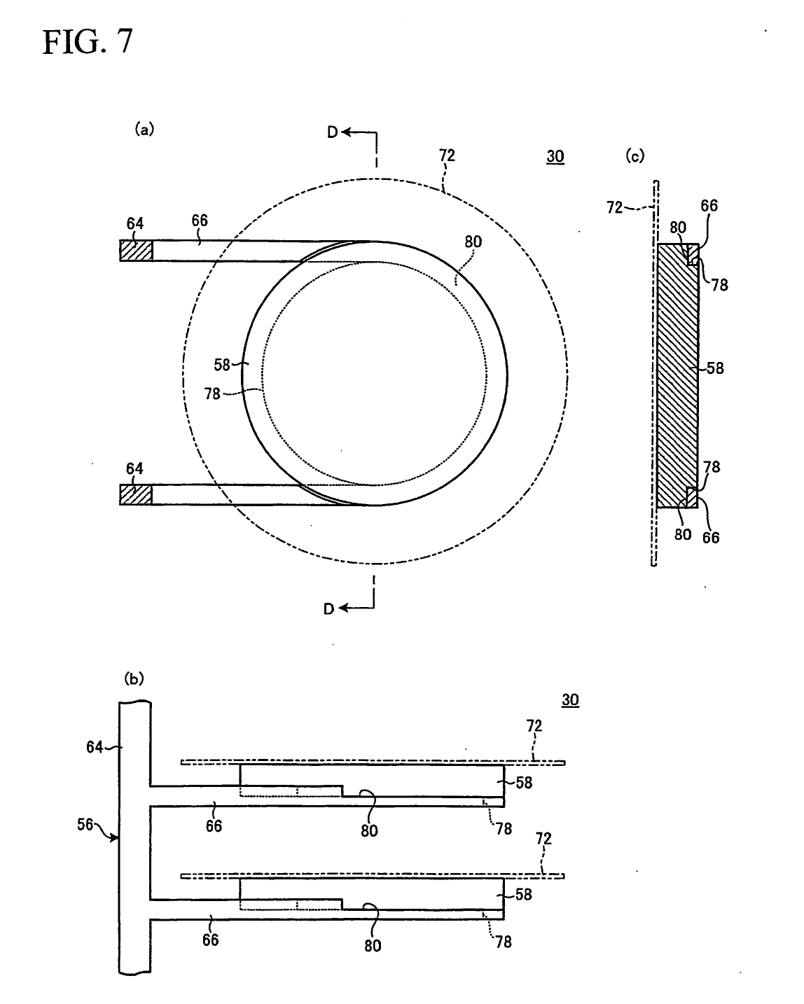

FIG. 7 shows a third modification of the first embodiment.

The third modification is different from the first embodiment described above in the shape of the supporting strip 66. The groove 80 (fitting portion) as a recess is formed on the upper surface of the supporting strip 66 in the vicinity of the substrate insertion side, and the width of the supporting strip 66 is equal to or smaller than the diameter of the supporting plate 58. The groove 80 of the supporting plate 66 is formed into a circular shape so as to match the shape of the supporting plate 58 when viewed from above, and the engaging groove 78 (fitting portion) provided on the outer peripheral portion of the back surface of the supporting plate 58 fits the groove 80 of the supporting strip 66, so that the outer peripheral portion of the supporting plate 58 is supported by the supporting strip 66.

By the mutual fitting between the groove 80 of the supporting strip 66 and the engaging groove 78 of the supporting plate 58, movement (displacement) of the supporting plate 58 with respect to the supporting strip 66 in any direction (horizontal direction) can be prevented.

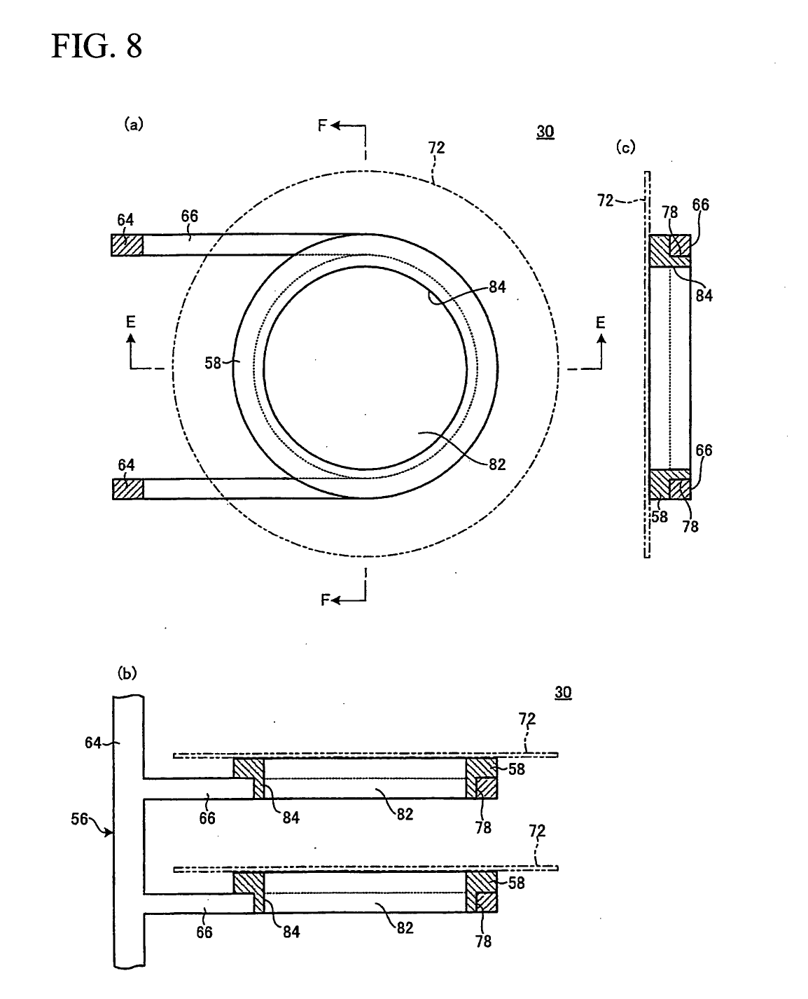

FIG. 8 shows a fourth modification of the first embodiment.

The fourth modification is different from the first embodiment described above in the shape of the supporting plate 58.

A non-contact portion 82 that communicates with the outside without coming into contact with the substrate 72 is provided on a substrate placing surface of the supporting plate 58. In the fourth modification of the first embodiment, the non-contact portion 82 is composed of, for example, a single through hole 84. The through hole 84 is provided at a center portion of the supporting plate 58, and is formed into a cylinder being concentric with the substrate 72 and having a cross-section which is a circle concentric with the substrate 72. One end of the through hole 84 opens on the substrate placing surface of the supporting plate 58 and the other end thereof opens on the lower surface of the supporting plate 58 so as to communicate with the outside. The projection plane obtained by projecting the through hole 84 of the supporting plate 58 in the direction of the plane thereof does not overlap with the projection plane obtained by projecting the supporting strip 66 in the direction of the plane. In other words, the supporting strip 66 is configured not to close the through hole 84 of the supporting plate 58.

As described later, the number of the through hole 84 is not limited to one, and a plurality of the through holes 84 can be provided. For example, the plurality of through holes can be provided around the through hole 84 at the center. The position of the through hole 84 is not limited to the center, but the plurality of through holes 84 may be provided on a portion other than the center.

In this manner, since the supporting strip 66 does not close the through hole 84 of the supporting plate 58 even in the case in which the supporting plate 58 having the through hole 84 is supported by the supporting strip 66, air between the substrate and the supporting plate can be released smoothly through the through hole 84 when placing the substrate, so that slippage of the substrate can be prevented.

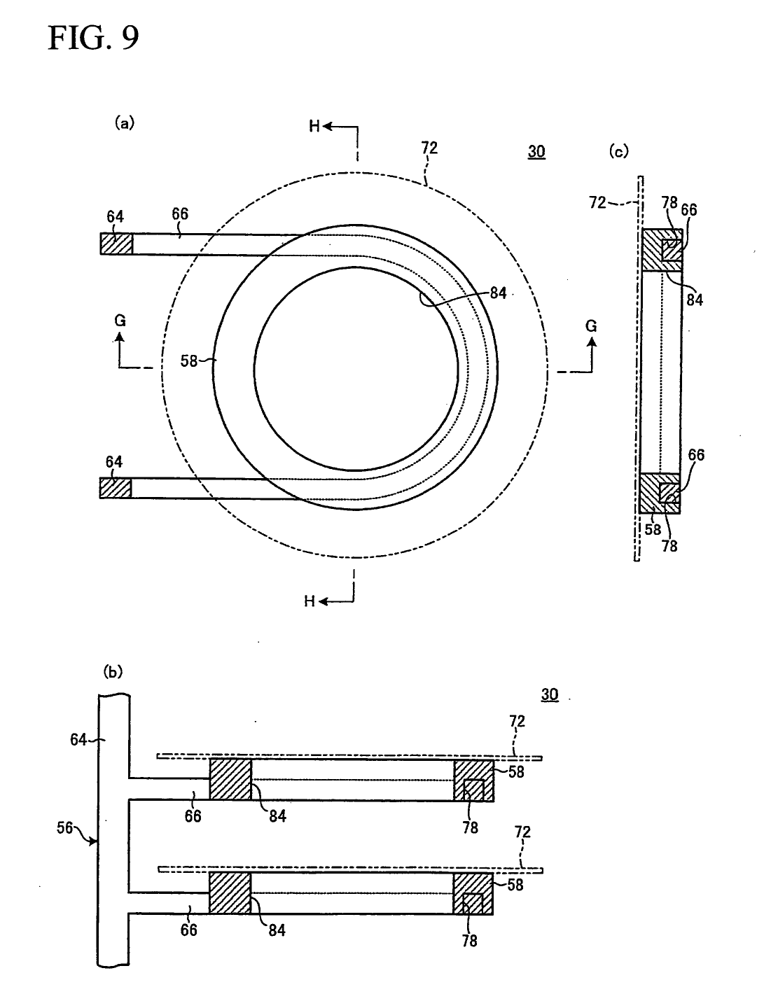

FIG. 9 shows a fifth modification of the first embodiment.

The fifth modification is different from the first embodiment described above in the shape of the supporting plate 58.

The diameter of the supporting plate 58 is larger than the width of the supporting strip 66, and the engaging groove 78 (fitting portion) in the shape of a recess is formed on the lower portion (back surface) of the supporting plate 58. The engaging groove 78 is formed into a U-shape so as to match the shape of the supporting strip 66 of the supporting tool 30. The engaging groove 78 engages with the supporting strip 66 and the supporting plate 58 is supported by the supporting strip 66. As in the case of the fourth modification of the first embodiment described above, for example, the single through hole is formed at the center of the supporting plate 58. The projection plane obtained by projecting the through hole 84 of the supporting plate 58 in the direction of the plane thereof does not overlap with the projection plane obtained by projecting the supporting strip 66 in the direction of the plane. In other words, the supporting strip 66 is configured not to close the through hole 84 of the supporting plate 58.

In this manner, since the supporting strip 66 does not close the through hole 84 of the supporting plate 58 even when the supporting plate 58 having the through hole 84 is supported by the supporting strip 66, air between the substrate and the supporting plate can be released smoothly through the through hole 84 when placing the substrate, so that slippage of the substrate can be prevented.

By the mutual fitting between the supporting strip 66 and the engaging groove 78 of the supporting plate 58, movement (displacement) of the supporting plate 58 with respect to the supporting strip 66 can be prevented in any direction (horizontal direction).

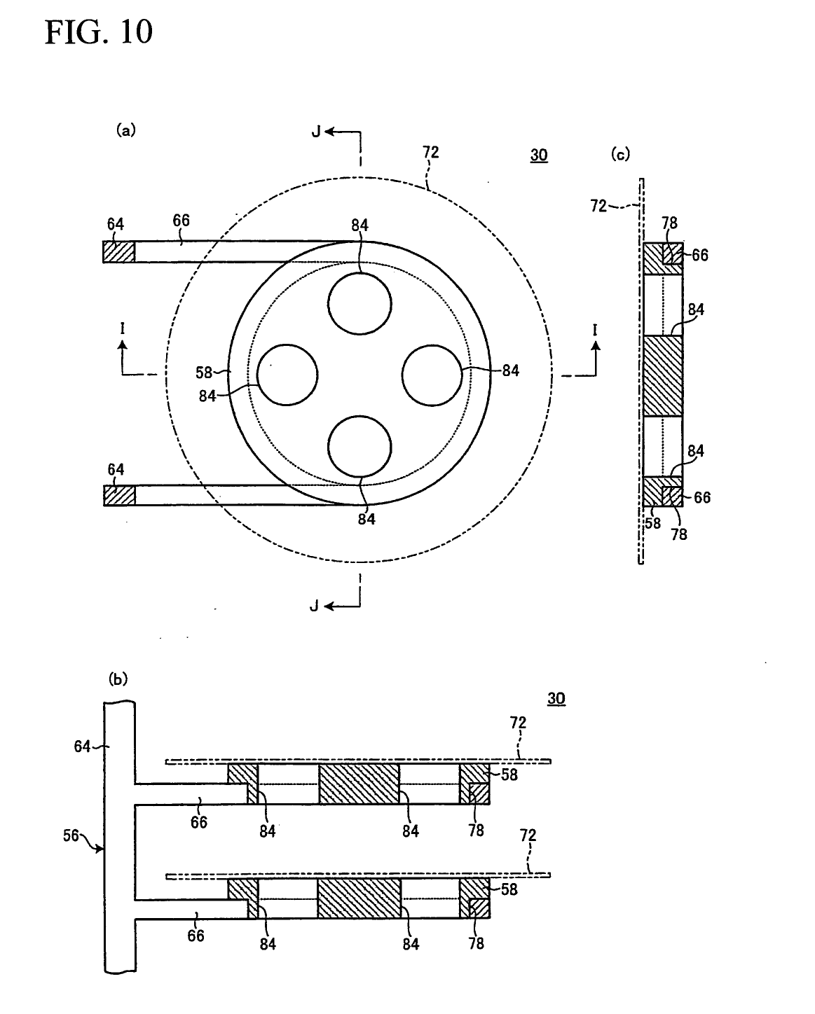

FIG. 10 shows a sixth modification of the first embodiment.

The sixth embodiment is different from the first embodiment described above in the shape of the supporting substrate 58.

The supporting substrate 58 includes, for example, four of the through holes 84. The through holes 84 are formed so that centers of the through holes 84 are positioned on a circle concentric to the supporting plate 58. The projection plane obtained by projecting the four through holes 84 of the supporting plate 58 in the direction of the plane thereof does not overlap with the projection plane obtained by projecting the supporting strip 66 in the direction of the plane. In other words, the supporting strip 66 is configured not to close all the four through holes 84 of the supporting plate 58.

In this manner, since the supporting strip 66 does not close the through holes 84 of the supporting plate 58 even when the supporting plate 58 having the plurality of through holes 84 is supported by the supporting strip 66, air between the substrate and the supporting plate can be released smoothly through the plurality of through holes 84 when placing the substrate, whereby slippage of the substrate can be prevented.

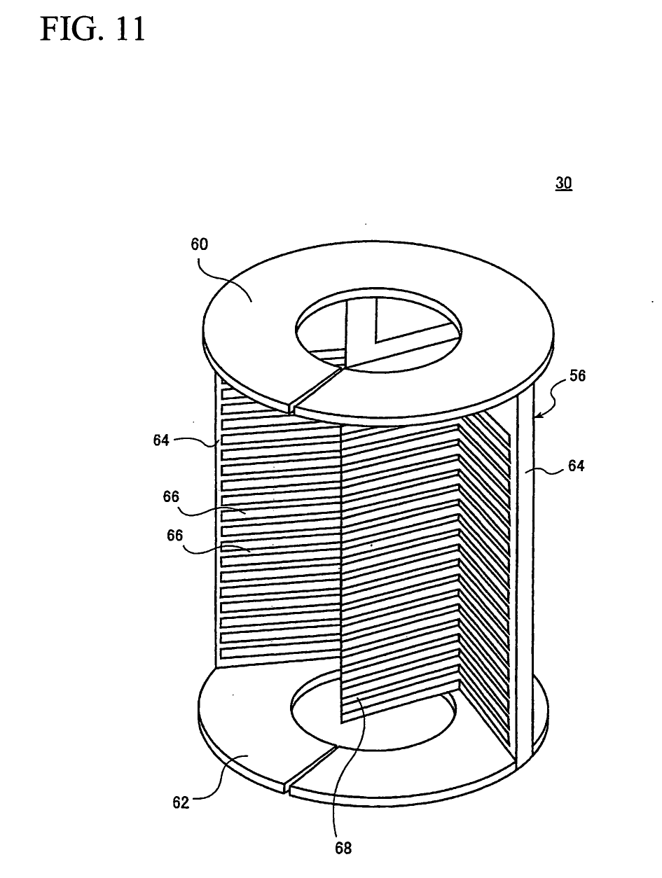

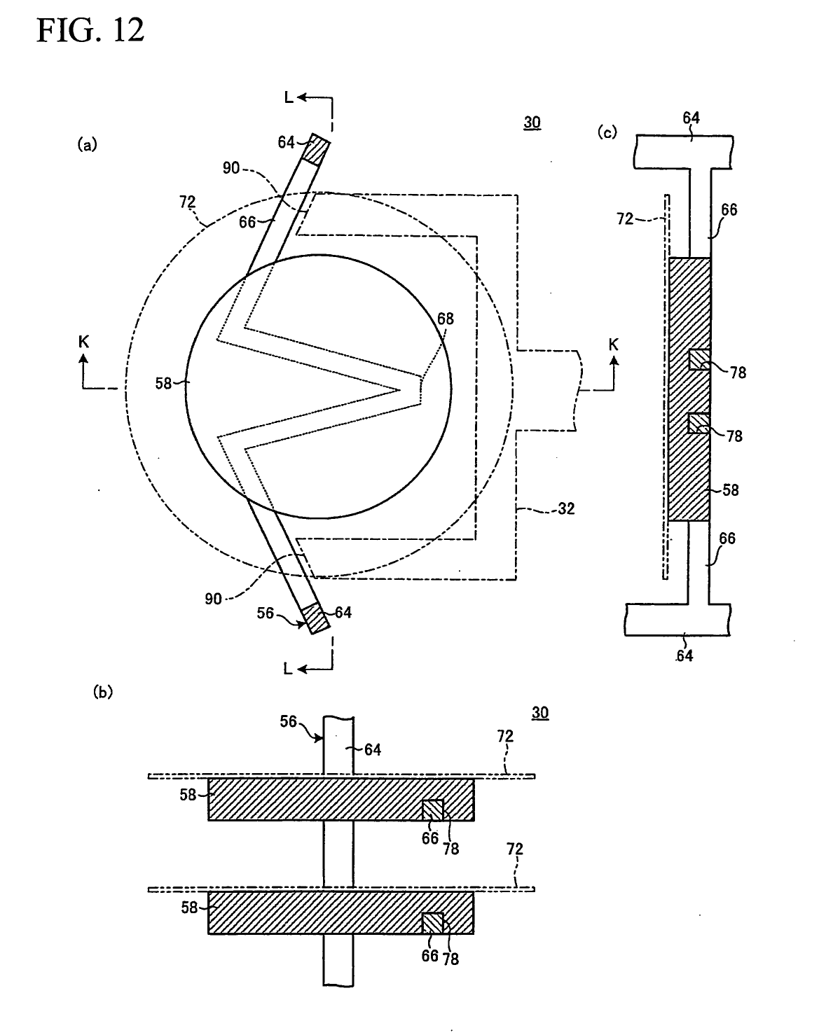

Subsequently, FIG. 11 and FIG. 12 show a second embodiment.

The second embodiment is different from the first embodiment described above in the shapes of the supporting strip 66 and the supporting plate 58. In other words, the supporting strip 66 is formed into an M-shape when viewed from above, extends horizontally, and is provided with the projection 68 projecting in a triangle shape toward a tweezers 32 insertion side (the side of the substrate transfer unit 26). A distal end of the projection 68 is protruded from a straight line that connects the two pillars 64, 64 toward the tweezers. A number of the supporting strips 66 are formed in the vertical direction with respect to the pillars 64 at regular intervals, and the supporting plates 58 are supported by a number of the supporting strips 66 respectively. The supporting plate 58 is formed into a disk-shape and the center of the supporting plate 58 is located on the straight line connecting the two pillars 64, 64. The substrate 72 is supported by the supporting plate 58 so that the center of the supporting plate 58 and the center of the substrate 72 coincide with each other.

When the supporting plate 58 is supported by the supporting strip 66, there arises a problem such that points of the supporting strip 66 that support the supporting plate 58 may be deformed due to the weight of the supporting plate 58. However, a center of gravity of the supporting plate 58 and the substrate 72 is located on the straight line that connects the two pillars 64, 64 and the supporting strip 66 has a laterally symmetric shape. Therefore, when the substrate 72 is placed on the supporting plate 58, the stress is applied to the two pillars 64, 64 equally, and hence even when the supporting strip 66 is deformed, the supporting plate 58 can hardly be inclined, and is deformed vertically. Therefore, displacement of the substrate 72 can be prevented, and stable treatment is achieved.

The engaging groove 78 (fitting portion) in the shape of a recess is provided on the lower portion (back surface) of the supporting plate 58. The engaging groove 78 is formed into an M-shape so as to match the shape of the supporting strip 66 of the supporting tool 30, and the engaging groove 78 is fitted to the supporting strip 66, whereby the supporting plate 58 is supported by the supporting strip 66. By the mutual fitting between the supporting strip 66 and the engaging groove 78 of the supporting plate 58, movement (displacement) of the supporting plate 58 with respect to the supporting strip 66 can be prevented in any direction (horizontal direction).

The depth of the engaging groove 78 in the direction of the thickness on the back surface of the supporting plate 58 described above is the same as the height of the supporting strip 66 in the direction of the thickness. In other words, the supporting plate 58 and the supporting strip 66 are overlapped partly with each other in the direction of thickness.

In this manner, with the structure in which the supporting plate 58 and the supporting strip 66 are overlapped at least partly with each other in the direction of the thickness, the total thickness of the supporting plate 58 and the supporting strip 66 in the state in which the supporting plate 58 is supported by the supporting strip 66 can be reduced, whereby the inter-substrate pitch can be reduced.

As in the first embodiment, the tweezers 32 can be inserted within the range of the thickness of the supporting strip 66 in the second embodiment as well. Distal ends of the tweezers 32 are formed with notches 90 which is obliquely cut out so as to match the shape of the supporting strip 66, whereby the substrate 72 can be supported in a state in which the distal ends of the tweezers 32 reach a position beyond the centerline of the substrate 72 without interference of the tweezers 32 with the supporting strip 66.

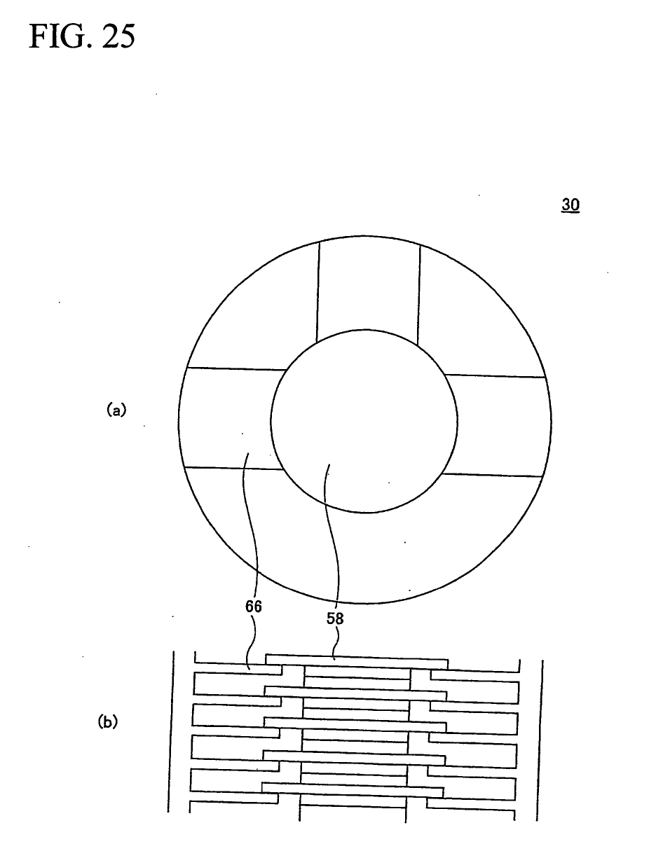

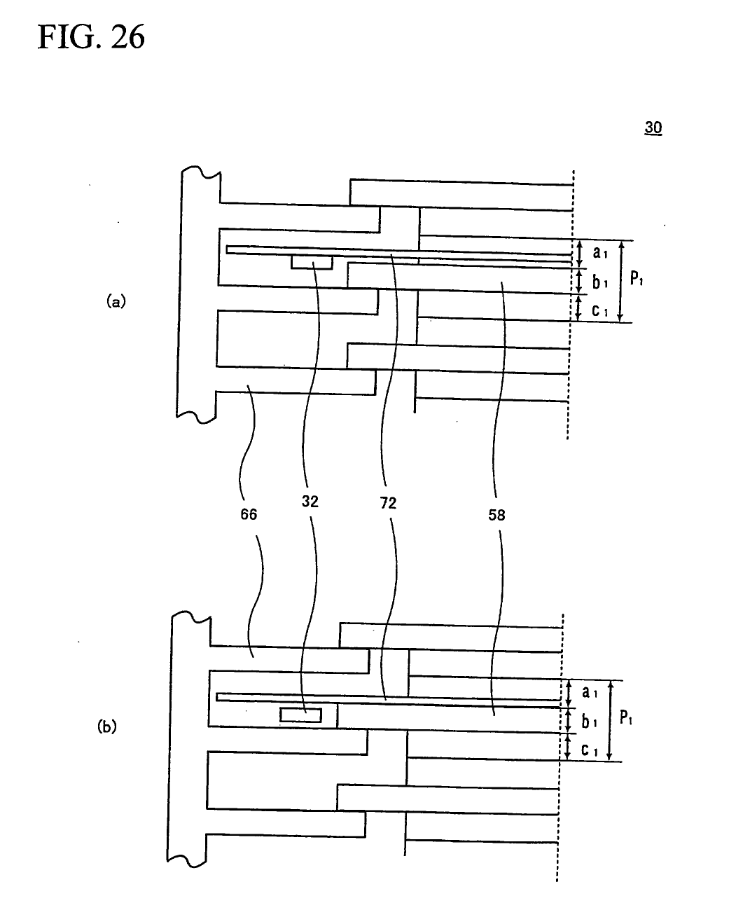

As described above, in the comparative examples shown in FIG. 25 and FIG. 26, it is necessary to set the thickness of the supporting plate 58 to at least 6.5 mm in order to avoid interference between the tweezers 32 and the supporting strip 66. On the other hand, in the second embodiment of the present invention, when the substrate 72 is placed on the supporting plate 58, since there is no supporting strip 66 below the tweezers 32, the tweezers 32 will never interfere with the supporting strip 66 even when the tweezers 32 are lowered too much. Therefore, it is not necessary to take the distance for avoiding interference, which has to be considered in the comparative example, into consideration, and the pitch can be reduced correspondingly.

In other words, although the thickness of the supporting plate 58 must be at least 6.5 mm for avoiding interference in the comparative example, in the above-described embodiments, it can be reduced to the order of 1 mm to 4 mm, or even to 1 mm or less. Consequently, the weight of the supporting plate 58 is reduced, and hence the thickness of the supporting strip 66 for supporting the same can be reduced correspondingly. Although at least the thickness of about 3 mm is necessary for the supporting strip 66 in the comparative example, it can be reduced to the order of 1.5 mm to 2 mm in the above-described embodiments. It is necessary to secure the clearance on the order of 4 mm for transferring the substrate 72 as in the comparative example.

From the reasons described above, the inter-substrate pitch must be 13.5 mm in the comparative example, it can be reduced to the order of 6.5 mm in the above described embodiments. However, when considering the limit of the pitch of the tweezers 32, the inter-substrate pitch is preferably on the order of 7.5 mm. In this case, the thicknesses of the supporting strip 66 and the supporting plate 58 can have flexibility to a certain extent. When the inter-substrate pitch is set to 7.5 mm, for example, the thickness of the supporting strip 66, the thickness of the supporting plate 58, and the clearance for transferring the substrate 72 might be set to 1.5 mm, 3.5 mm and 4 mm respectively.

The shape of the supporting strip 66 is not limited to the M-shape.

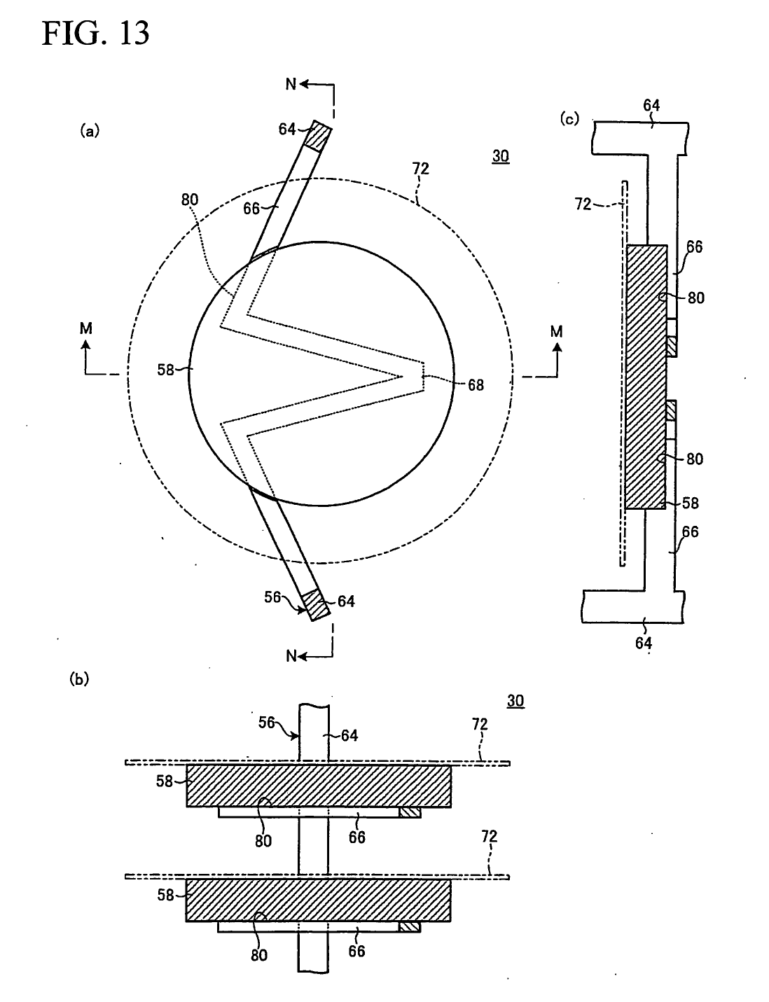

FIG. 13 shows a first modification of the second embodiment.

The first modification is different from the second embodiment described above in the shapes of the supporting strip 66 and the supporting plate 58.

The groove 80 (fitting portion) in the shape of a recess is provided on the upper surface of the supporting strip 66 in the vicinity of the projection 68. The groove 80 of the supporting strip 66 is formed into a circular shape having substantially the same diameter as the diameter of the supporting plate 58 when viewed from above so as to match the shape of the supporting plate 58, and the lower portion (back surface) of the supporting plate 58 comes into contact with the groove 80 of the supporting strip 66, whereby the supporting plate 58 is supported by the supporting strip 66. On the other hand, the supporting plate 58 is formed into a simple disk-shape having no projection and depression on the lower portion (back surface).

In this manner, by the mutual fitting between the groove 80 of the supporting strip 66 and the supporting plate 58, movement (displacement) of the supporting plate 58 in the direction of insertion of the substrate with respect to the supporting strip 66 can be prevented. In other words, even when a force in the direction of insertion of the substrate is applied to the supporting plate 58, the outer peripheral surface (end surface) of the supporting plate 58 comes into abutment with the side wall of the groove 80 of the supporting strip 66, and hence movement (displacement) of the supporting plate 58 with respect to the supporting strip 58 can be prevented.

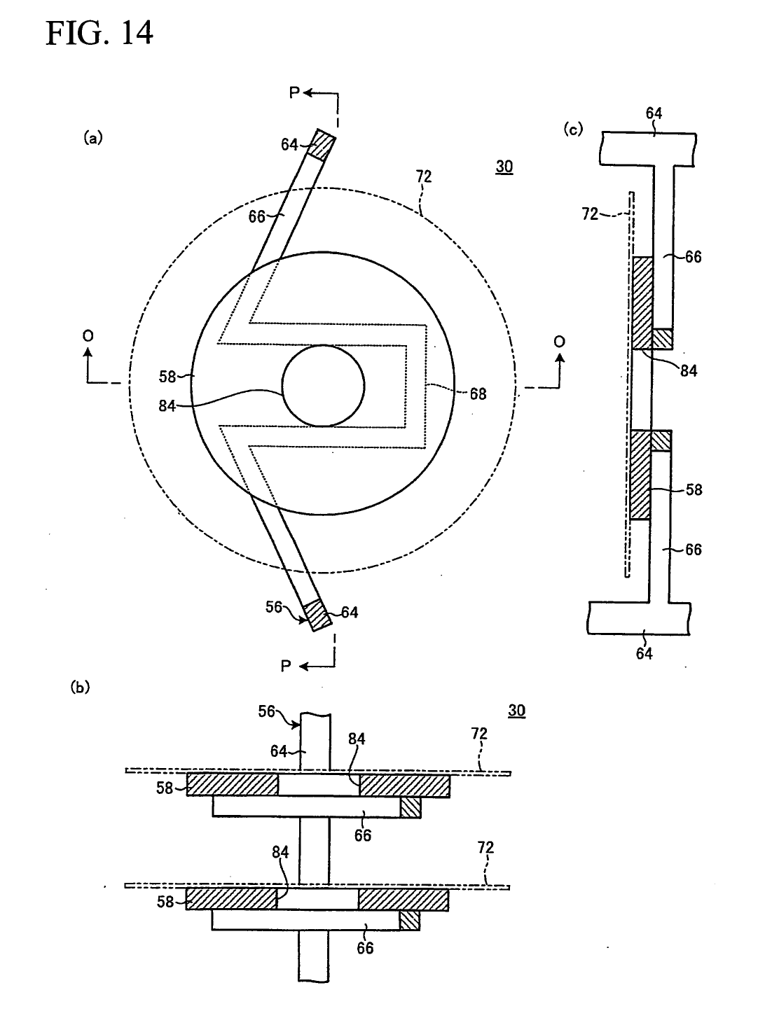

FIG. 14 shows a second modification of the second embodiment.

The second modification is different from the second embodiment described above in the shapes of the supporting strip 66 and the supporting plate 58.

The supporting strip 66 includes the projection 68 projecting substantially in U-shape toward the tweezers 32 insertion side (the side of the substrate transfer unit 26). On the other hand, the supporting plate 58 is formed with, for example, the single through hole 84 at the center of the supporting plate 58, The through hole 84 is provided at a center portion of the supporting plate 58, and is formed into a cylinder being concentric with the substrate 72 and having a cross-section which is a circle concentric with the substrate 72. One end of the through hole 84 opens on the substrate placing surface of the supporting plate 58 and the other end thereof opens on the lower surface of the supporting plate 58 so as to communicate with the outside. The projection plane obtained by projecting the through hole 84 of the supporting plate 58 in the direction of the plane thereof does not overlap with the projection plane obtained by projecting the supporting strip 66 in the direction of the plane. In other words, the supporting strip 66 is configured not to close the through hole 84 of the supporting plate 58.

The number of the through hole 84 is not limited to one, and the plurality of through holes 84 can be provided. For example, the plurality of through holes 84 can be provided around the through hole 84 at the center. It is also possible to form the through hole 84 not at the center of the substrate placing surface, but the plurality of through holes 84 may be provided on a portion other than the center.

In this manner, since the supporting strip 66 does not close the through hole 84 of the supporting plate 58 even in the case in which the supporting plate 58 having the through hole 84 is supported by the supporting strip 66, air between the substrate 72 and the supporting plate 58 can be released smoothly through the through hole 84 when placing the substrate, so that slippage of the substrate can be prevented.

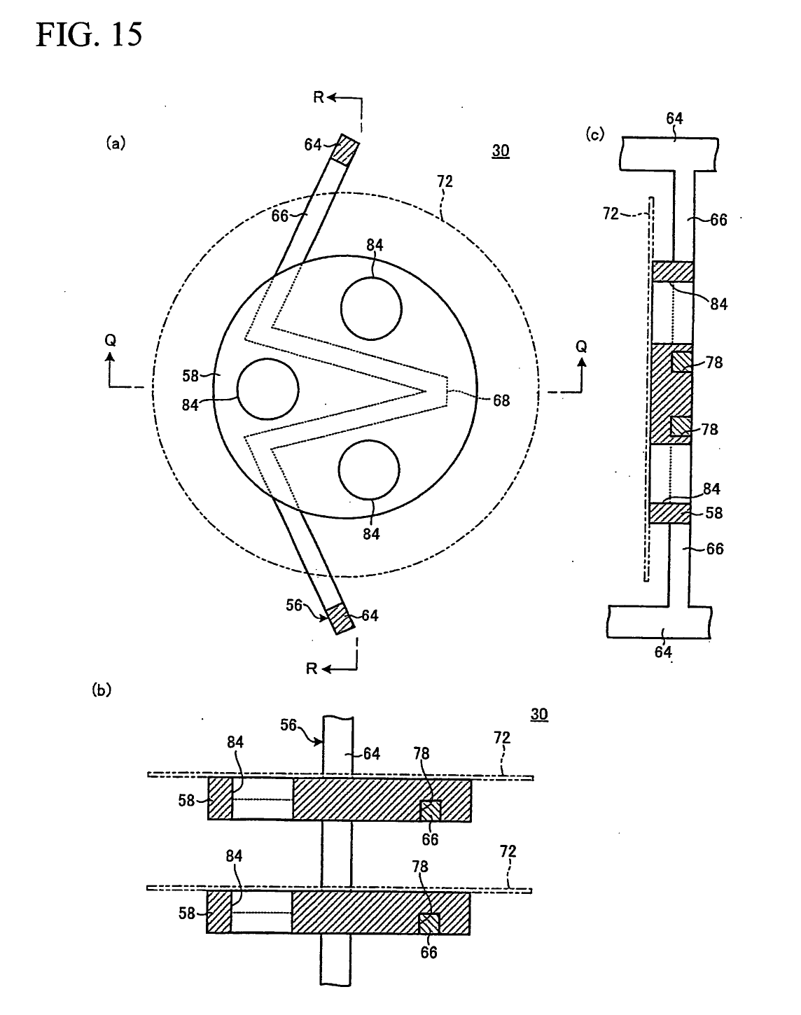

FIG. 15 shows a third modification of the second embodiment.

The third modification is different from the second embodiment described above in the shape of the supporting plate 58.

The supporting plate 58 includes, for example, three through holes 84. These through holes 84 are formed to be positioned so that the centers of the through holes 84 are positioned on a circle concentric to the supporting plate 58. The projection plane obtained by projecting the three through holes 84 of the supporting plate 58 in the direction of the plane thereof does not overlap with the projection plane obtained by projecting the supporting strip 66 in the direction of the plane. In other words, the supporting strip 66 is provided in a serpentined manner so as to avoid interference with the three through holes 84, whereby all the three through holes 84 of the supporting plate 58 are not closed.

In this manner, since the supporting strip 66 does not close the through holes 84 of the supporting plate 58 even when the supporting plate 58 having the through holes 84 is supported by the supporting strip 66, air between the substrate and the supporting plate can be released smoothly through the plurality of through holes 84 when placing the substrate, so that slippage of the substrate can be prevented.

The engaging groove 78 (fitting portion) is provided on the lower portion (back surface) of the supporting plate 58. The engaging groove 78 is formed into an M-shape so as to match the shape of the supporting strip 66 of the supporting tool 30, and the engaging groove 78 is fitted to the supporting strip 66, so that the supporting plate 58 is supported by the supporting strip 66. By the mutual fitting between the supporting strip 66 and the engaging groove 78 of the supporting plate 58, movement (displacement) of the supporting plate 58 with respect to the supporting strip 66 can be prevented in the horizontal direction.

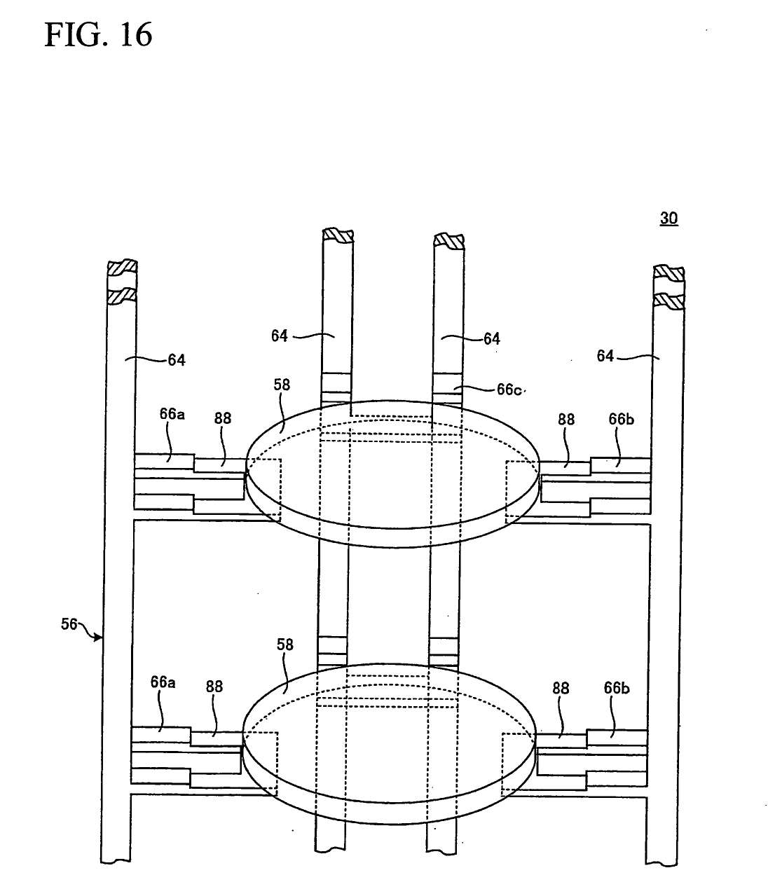

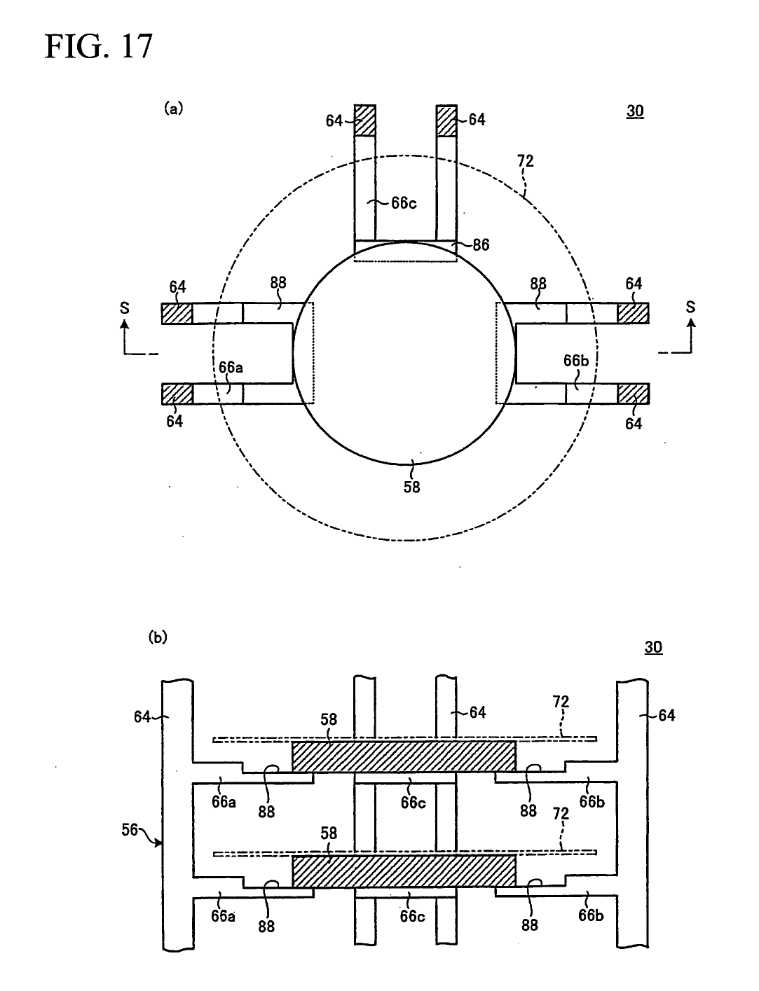

FIGS. 16 to 19 show a third embodiment.

The third embodiment is different from the first embodiment described above in the shapes of the supporting strip 66 and the supporting plate 58.

In FIGS. 16 to 19, the supporting tool 30 includes the body portion 56 and the supporting plate 58. The body portion 56 is formed of silicon carbide (SiC) or silicon carbide impregnated with silicon, and includes the upper plate 60 (shown in FIG. 1) of the disk-shape, the lower plate 62 (shown in FIG. 1) also of the disk-shape, three sets of, for example, two pillars 64, 64 for connecting the upper plate 60 and the lower plate 62, and supporting strips 66a, 66b, 66c that extend from the three sets of pillars 64, 64. The three sets of pillars 64, 64 are arranged so as to be apart from each other by 90°, two sets on the tweezers 32 insertion side at positions 180° apart from each other and one set on the opposite side from the tweezers 32 insertion side (the side opposite from the side on which the tweezers is inserted). The supporting strips 66a-66c are formed, for example, into the substantially U-shape, and extend horizontally from the three sets of pillars 64, 64, respectively. A number of the supporting strips 66a to 66c are formed in the vertical direction with respect to the pillars 64, 64 at regular intervals, and a number of the supporting strips 66a-66c support the supporting plates 58 respectively. The substrate 72 is supported so that the lower surface of the substrate 72 comes into contact with the upper surface of the supporting plate 58.

As in the case of the first embodiment, the supporting strips 66a-66c are integrally formed with the three sets of pillars 64, 64 respectively so as to connect the three sets of two pillars 64, 64 respectively. The supporting tool 30 of this embodiment includes three sets of the pillars 64 and the supporting strip 66 according to the first embodiment but being slimmer (downsized) than those in the first embodiment, arranged apart from each other by 90°. The supporting strips 66a-66c and the three sets of pillars 64, 64 are integrally formed respectively by cutting out, for example, three pillar shaped members so as to leave portions that correspond to the supporting strips 66a-66c and three sets of pillars 64.

The supporting plate 58 is formed, for example, of silicon (Si) into a disk-shape. The supporting plate 58 in the third embodiment is different from the supporting plate 58 in the first embodiment in that the engaging groove 78 is not formed on the back surface of the supporting plate 58.

The tweezers 32 of the substrate transfer unit 26 are bifurcated and formed substantially into a U-shape. The width between inner sides of the tweezers 32 is larger than the diameter of the supporting plate 58, and the tweezers 32 can be inserted into the supporting tool 30 in the range including part of the thickness of the supporting plate 58.

Recesses 88 are formed on the upper surfaces of the supporting strips 66a, 66b on both sides arranged on the side on which the tweezers 32 are inserted at a position to be opposed to the tweezers 32 when transferring the substrate. The recesses 88 are formed by thinning distal end portions of the supporting strips 66a, 66b while leaving the thickness of root portions thereof (on the side of the pillars 64, 64) corresponding to the tweezers 32, and the thinned portions include position where the supporting plate 58 is placed and the positions where the tweezers 32 are inserted. In other words, the recesses 88 are formed from the portions of the supporting strips 66a, 66b that are to be opposed to the tweezers when transferring the substrate to the end portions thereof where the supporting plate 58 is supported.

In this manner, with the structure in which the recesses 88 are formed on the upper surfaces of the supporting strips 66a, 66b at the portions that are to be opposed to the tweezers 32 at least when transferring the substrate, even when the supporting strips 66a, 66b are positioned below the tweezers 32 when transferring the substrate, the total thickness of the supporting plate 58 and the supporting strips 66a, 66b in a state in which the supporting plate 58 is supported by the supporting strips 66a-66c can be reduced, whereby the inter-substrate pitch can be reduced.

In other words, since it is configured to allow insertion of the tweezers in the range including at least part of the supporting strips 66a, 66b, the inter-substrate pitch can be reduced at least by an amount corresponding to the part of the thickness of the supporting strips 66a, 66b.

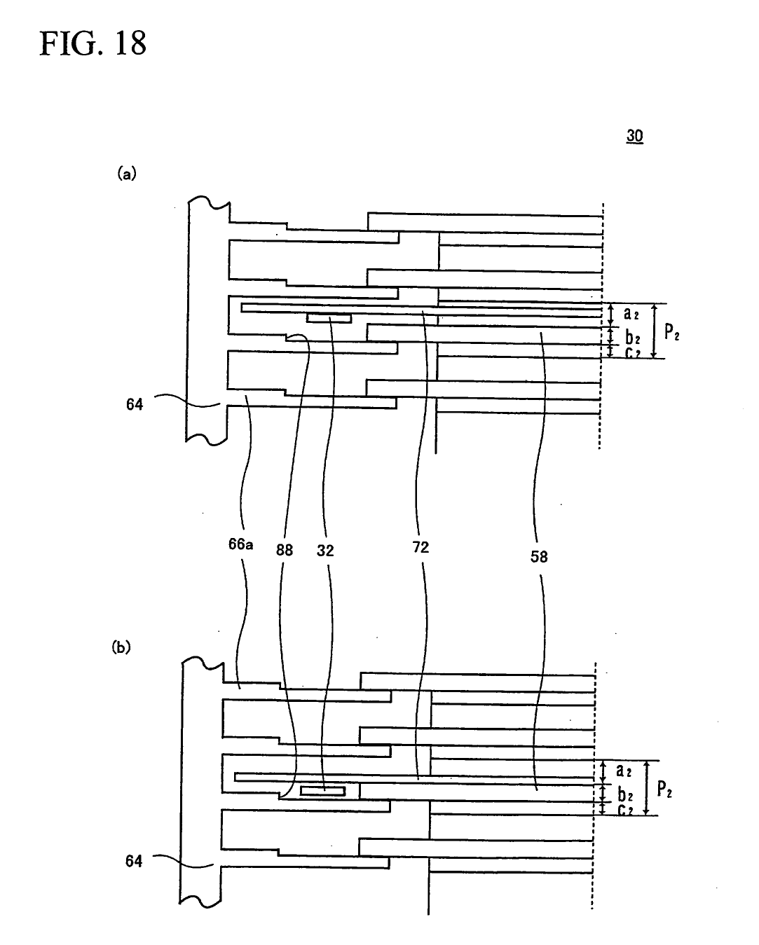

In other words, as shown in FIG. 18, assuming that a2 represents the thickness of the substrate when inserting the substrate+upper and lower clearances, b2 represents the thickness of the tweezers when the tweezers are moved downward+upper and lower clearances, and c2 represents the thickness of the distal end portions (thinned portions) formed with the recesses 88 of the supporting strips 66a, 66b, an inter-substrate pitch P2 is expressed by a2+b2+c2.

Therefore, in comparison with the example in the related art shown in FIG. 26, a relation c2<c1 is satisfied by an amount corresponding to the recess 88, and the inter-substrate pitch may be P2<P1.

In other words, since the recesses 88 corresponding to the tweezers 32 are provided on the upper surfaces of the supporting strips 66a, 66b, the tweezers can run out by the amount corresponding to the recesses 88 of the supporting strips, whereby the inter-substrate pitch can be reduced.

Since the thickness of the root portions (side of the pillar 64) of the supporting strips 66a, 66b is the same as in the related art, the strength of the supporting strips 66a, 66b, 66c can be maintained to an extent substantially the same as in the related art. The thickness of the root portions of the supporting strips 66a, 66b is set so that the upper surfaces of the supporting strips 66a, 66b come higher than the upper surface of the supporting plate 58 to avoid contact between the substrate 72 and the root portions of the supporting strips 66a, 66b.

On the other hand, the supporting strip 66c arranged on the side opposite from the tweezers 32 insertion side is located at a position that does not interfere with the tweezers 32, it is not necessary to form a recess for avoiding interference with the tweezers 32. However, a shoulder 86 is formed at the distal end of the upper surface of the supporting strip 66c so as to be aligned with the upper surfaces of the recesses 88 of the supporting strips 66b, 66b.

Subsequently, a method of transferring the substrate 72 to the supporting tool 30 will be described.

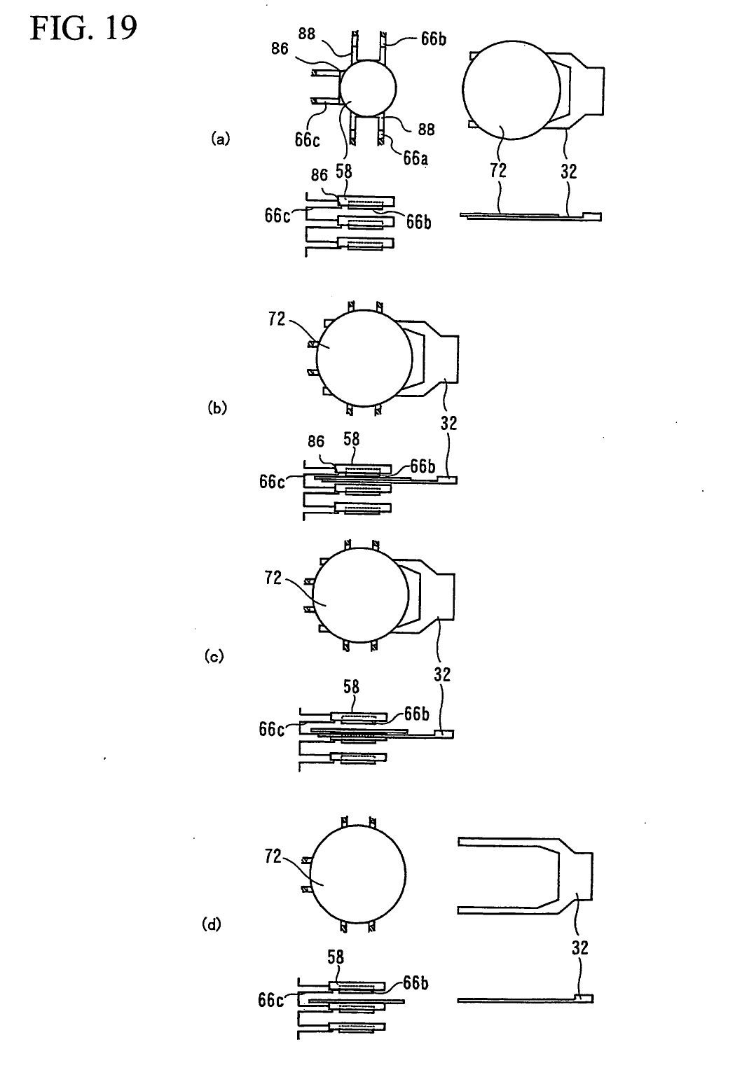

The supporting tool 30 has the supporting plates 58 placed in advance. As shown in FIG. 19(a), the substrate 72 is placed on the tweezers 32. Then, as shown in FIG. 19(b), the tweezers 32 having the substrate 72 placed thereon are inserted into a space formed between the supporting plate 58 and upper portions of the supporting strips 66a, 66b, 66c, and the supporting plate 58 and the lower portions of the supporting strips 66a, 66b, 66c provided adjacently above. At this time, the tweezers 32 are inserted to a position above the recesses 88 formed on the supporting strips 66a, 66b on both sides of the supporting plate 58. Subsequently, as shown in FIG. 19(c), the substrate 72 is placed on the supporting plate 58 by moving the tweezers 32 downward by a predetermined distance. At this time, since the recesses 88 are formed on the upper surfaces of the supporting strips 66a, 66b on both sides, interference between the tweezers 32 and the supporting strips 66a, 66b is avoided by the recesses 88. In other words, the tweezers 32 can be moved to the level lower than the upper surfaces of the root portions of the supporting strips 66a, 66b while avoiding interference between the tweezers 32 and the supporting strips 66a, 66b. Then, as shown in FIG. 19(d), by pulling the tweezers 32 out, transfer of the substrate 72 to the supporting tool 30 is completed.

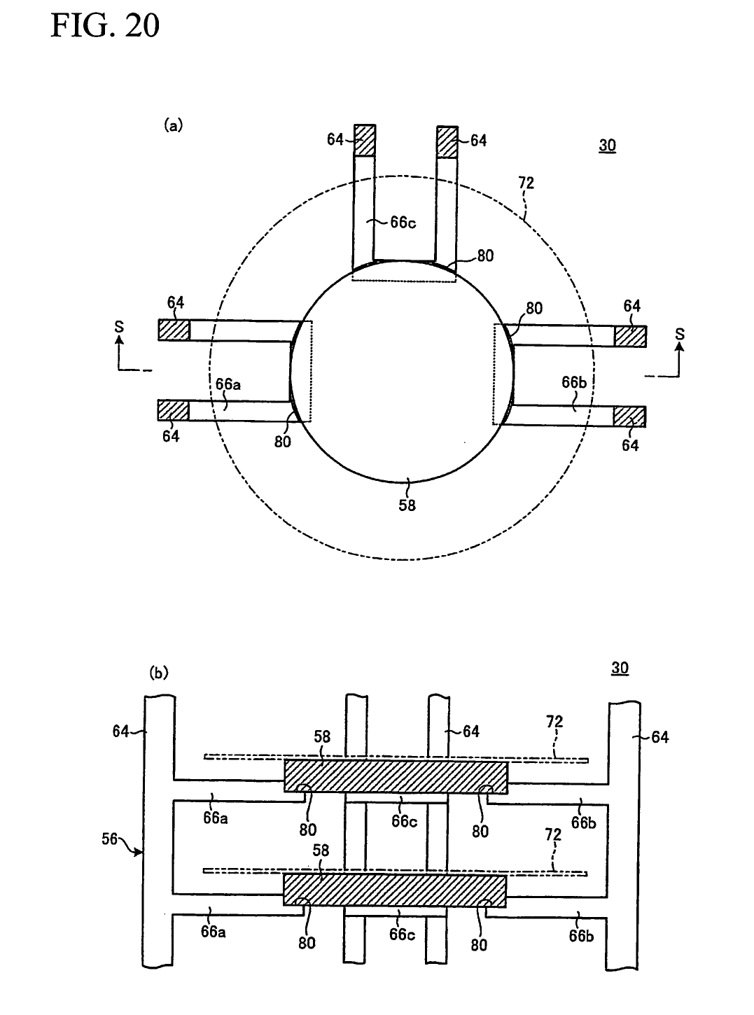

FIG. 20 shows a first modification of the third embodiment.

The first modification is different from the third embodiment described above in the shapes of the supporting strips 66a, 66b, 66c.

The supporting tool 30 includes the plurality of pillars 64, and the supporting strips 66a, 66b, 66c are integrally formed with three sets of pillars 64, 64 so as to connect the three sets of two pillars 64, 64 respectively, and the supporting strips 66a-66c and the pillars 64 are formed with SiC impregnated with Si.

The grooves 80 (fitting portions) in the shape of a recess are formed on the upper surfaces of the supporting strips 66a, 66b, 66c. The grooves 80 of the supporting strips 66a, 66b, 66c are provided at portions that come into contact with the back surface of the supporting plate 58 on the upper surfaces of the supporting strips 66a, 66b, 66c, and are formed into a circular shape having substantially the same diameter as the diameter of the supporting plate 58 when viewed from above. The lower portion (back surface) of the supporting plate 58 comes into contact with the grooves 80 on the supporting strips 66a, 66b, 66c, and the supporting plate 58 is supported by the supporting strips 66a, 66b, 66c. In other words, the supporting strips 66a, 66b, 66c are provided with the grooves 80 (fitting portions) for achieving mutual fitting with each other (supporting plate 58 and supporting strips 66a-66c), and are configured so that the supporting plate 58 and supporting strips 66a, 66b, 66c are overlapped with each other partly in the direction of the thickness.

In this manner, with the structure in which the supporting plate 58 and the supporting strips 66a-66c are overlapped at least partly in the direction of the thickness, that is, with the structure in which the depth of the groove 80 and the width (height) of the supporting strips 66a-66c are overlapped in the direction of the thickness, the total thickness of the supporting plate 58 and the supporting strips 66a-66c in the state in which the supporting plate 58 is supported by the supporting strips 66a-66c can be reduced, and the inter-substrate pitch can be reduced.

As described above, with the provision of the grooves 80 (fitting portions) on the supporting strips 66a-66c for achieving the mutual fitting with each other (the supporting plate 58 and the supporting strips 66a-66c), positioning of the supporting plate 58 with respect to the supporting strips 66a-66c is enabled, and displacement of the supporting plate 58 and dropping-out of the supporting plate 58 can be prevented. In other words, by the mutual fitting between the grooves 80 of the supporting strips 66a, 66b, 66c and the supporting plate 58 of substantially the same diameter, movement (displacement) of the supporting plate 58 with respect to the supporting strips 66a, 66b, 66c toward the side of the roots of the respective supporting strips 66a, 66b, 66c can be prevented. For example, even when a force in the direction of insertion of the substrate is applied to the supporting plate 58, the outer peripheral surface (end surface) of the supporting plate 58 comes into abutment with the side walls of the grooves 80 of the supporting strips 66a, 66b, 66c, and hence movement (displacement) of the supporting plate 58 with respect to the supporting strips 66a, 66b, 66c can be prevented.

As described above, the supporting tool 30 includes the plurality of pillars 64, the supporting strips 66a, 66b, 66c are integrally formed with the three sets of pillars 64, 64 respectively so as to connect the three sets of two pillars 64, 64 respectively, and the supporting strips 66a-66c and the pillars 64 are formed of SiC impregnated with Si. The body portion 56 formed of SiC impregnated with Si, that is, the plurality of pillars 64 and the supporting strips 66a-66c can be manufactured as a single unit while maintaining the strength.

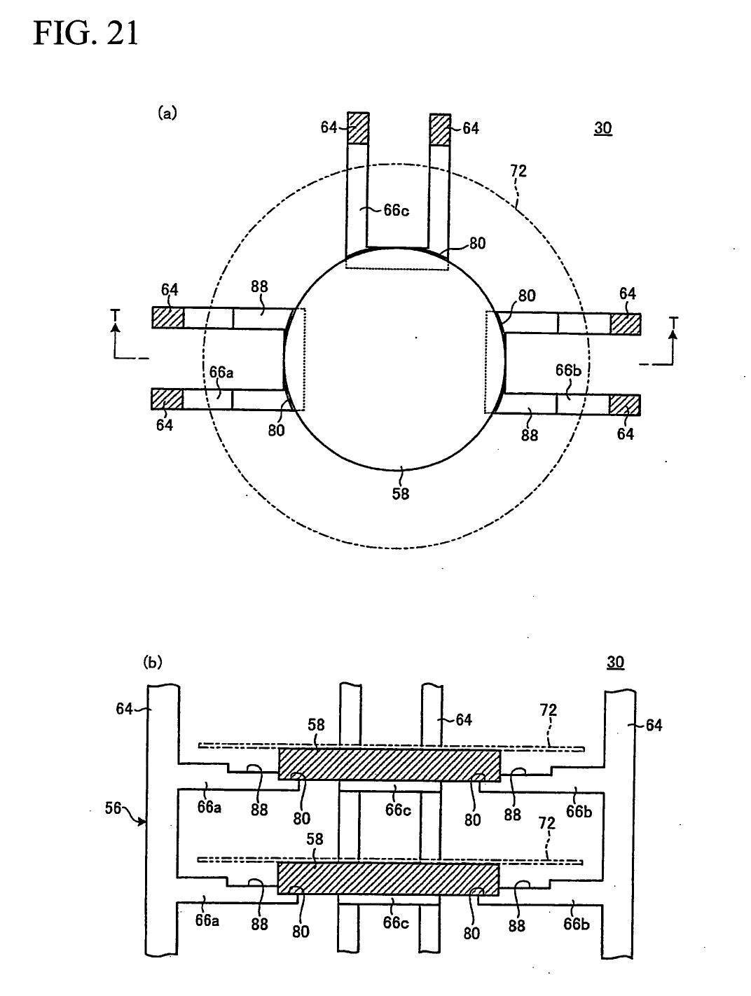

FIG. 21 shows a second modification of the third embodiment.

The second modification is different from the third embodiment described above in the shapes of the supporting strips 66a, 66b, 66c.

The grooves 80 (fitting portions) are provided on the distal end portions of the upper surfaces of the supporting strips 66a, 66b, 66c. The grooves 80 of the supporting strips 66a, 66b, 66c are formed into a circular shape having substantially the same diameter as that of the supporting plate 58 when viewed from above so as to match the shape of the supporting plate 58, and the lower portion (back surface) of the supporting plate 58 comes into contact with the grooves 80 of the supporting strips 66a, 66b, 66c, and the supporting plate 58 is supported by the supporting strips 66a, 66b, 66c.

In this manner, by the mutual fitting between the grooves 80 of the supporting strips 66a, 66b, 66c and the supporting plate 58 having substantially the same diameter, movement (displacement) of the supporting plate 58 toward the side of the roots of the supporting strips 66a, 66b, 66c with respect to the supporting strips 66a, 66b, 66c can be prevented. For example, even when a force in the direction of insertion of the substrate is applied to the supporting plate 58, the outer peripheral surface of the supporting plate 58 comes into abutment with the side walls of the grooves 80 of the supporting strips 66a, 66b, 66c, and hence movement (displacement) of the supporting plate 58 with respect to the supporting strips 66a, 66b, 66c can be prevented.

The recesses 88 are formed on the upper surfaces of the both supporting strips 66a, 66b arranged on both sides where the tweezers 32 are inserted, at least at portions to be opposed to the tweezers 32. The recesses 88 are formed by thinning at least portions of the supporting strips 66a, 66b to be opposed to the tweezers 32 while leaving the thickness of the root portions thereof (on the pillars 64 side) corresponding to the tweezers 32, and the thinned portions extend from the outsides of positions where the tweezers 32 are inserted to the portions on the near sides of the positions where the supporting plates 58 are placed. The position where the supporting plate 58 is placed, that is, the grooves 80 are thinner than the recessed portions 88. In other words, the supporting strips 66a, 66b are thinned in two steps, that is, thinned at portions corresponding to the recesses 88, and are further thinned corresponding to the grooves 80 while leaving the thickness of the root portions.

In the second modification, the supporting portion 58 and the supporting strips 66a, 66b are overlapped with each other at least partly in the direction of the thickness, that is, by an amount corresponding to the sum of the depths of the grooves 80 and the recesses 88 of the supporting strips 66a, 66b in the direction of the thickness, and hence the total thickness of the supporting plate 58 and the supporting strips 66a, 66b can be reduced correspondingly, whereby the inter-substrate pitch can be reduced.

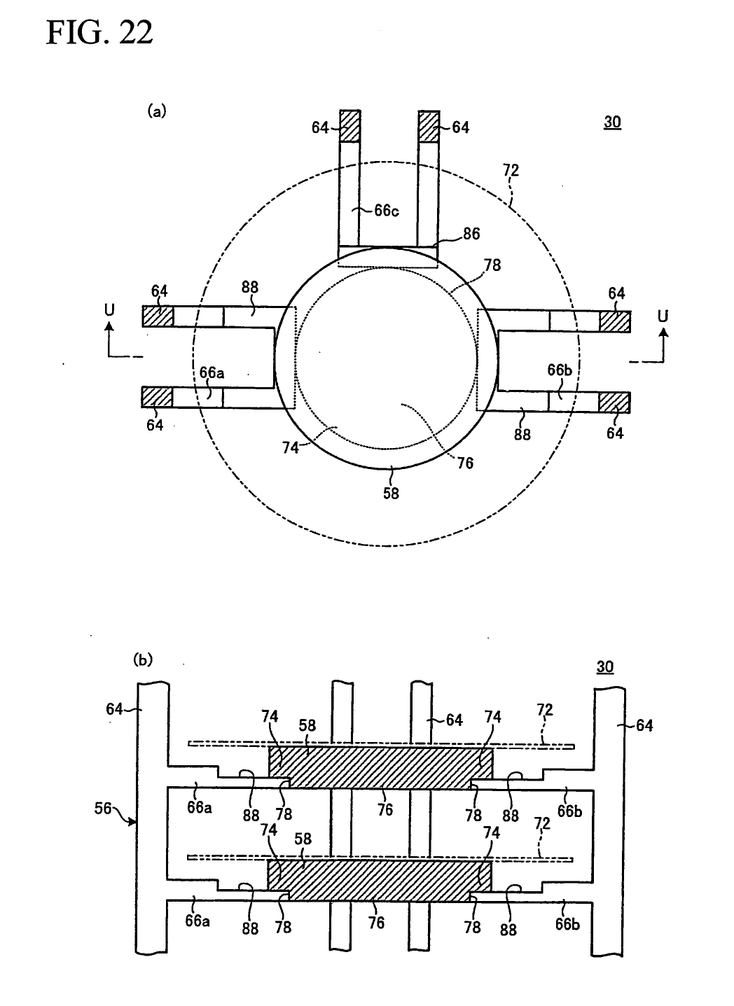

FIG. 22 shows a third modification of the third embodiment.

The third modification is different from the third embodiment described above in the shape of the supporting plate 58.

The supporting plate 58 includes the thin peripheral portion (outer peripheral portion) 74 and the thick central portion 76, and the engaging groove 78 (fitting portion) is formed on the lower portion (back surface) of the peripheral portion 74. The supporting plate 58 is supported by the supporting strips 66a, 66b, 66c by mutual fitting between the engaging groove 78 of the supporting plate 58 and the distal end portions of the supporting strips 66a, 66b, 66c.

By the mutual fitting between the distal end portions of the supporting strips 66a, 66b, 66c, and the engaging groove 78 of the supporting plate 58, the supporting strip 66 can prevent movement (displacement) of the supporting plate 58 with respect to the supporting strips 66a, 66b, 66c in the direction toward the side of the roots of the supporting strips 66a, 66b, 66c. For example, even when a force in the direction of insertion of the substrate is applied to the substrate 58, since the outer peripheral surface of the portion of the engaging groove 78 on the supporting plate 58 is in abutment with the distal ends of the supporting strips 66a, 66b, 66c, movement (displacement) of the supporting plate 58 with respect to the supporting strips 66a, 66b, 66c can be prevented.

The recesses 88 are formed on the upper surfaces of the supporting strips 66a, 66b arranged on both sides on which the tweezers 32 are inserted. The recesses 88 are formed by thinning the distal end portions of the supporting strips 66a, 66b while leaving the thickness of the root portions thereof corresponding to the tweezers 32, and are thinned portion thereof include position where the supporting plate 58 is placed and the position where the tweezers 32 are inserted. Since the thickness of the portions of the supporting strips 66a, 66b corresponding to the tweezers 32 can be reduced, the inter-substrate pitch can be reduced.

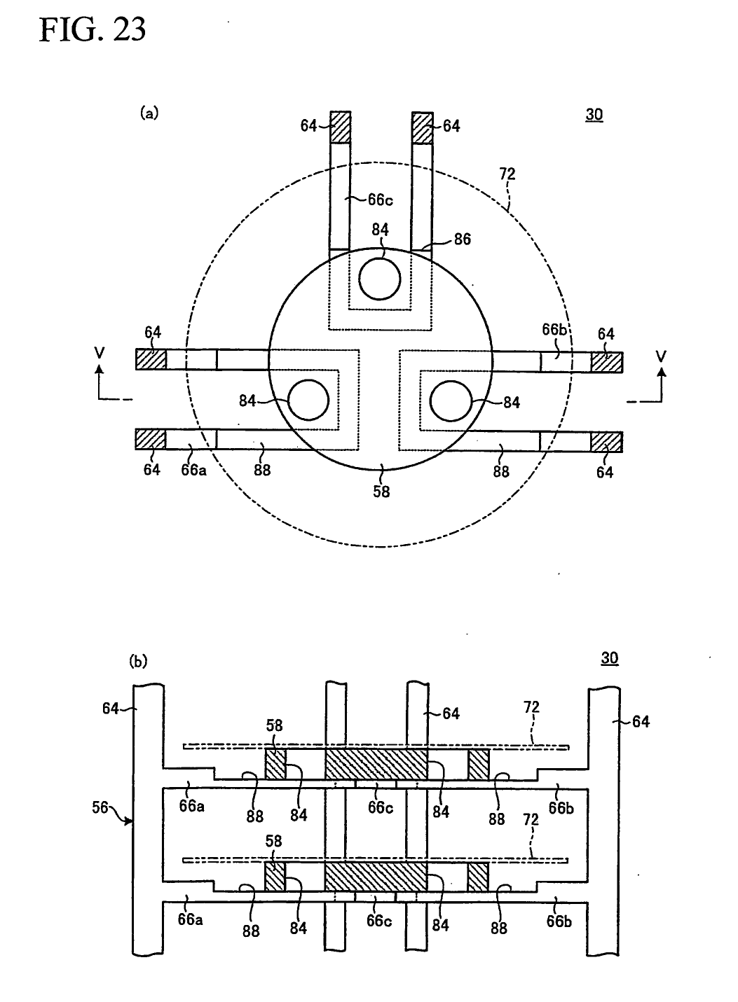

FIG. 23 shows a fourth modification of the third embodiment.

The fourth embodiment is different from the third embodiment described above in the shapes of the supporting plate 58 and the supporting strips 66a, 66b, 66c.

As regards the supporting strips 66a, 66b, 66c, the distances among the distal end of the supporting strip 66a, the distal end of the supporting strip 66b, and the distal end of the supporting strip 66c are shorter than in the case of the third embodiment. In other words, the respective supporting strips 66a, 66b, 66c are formed longer toward the center of the supporting tool 30 in a horizontal plane.

On the other hand, the supporting plate 58 includes, for example, the three through holes 84. These through holes 84 are formed, for example, in such a manner that the centers of the through holes 84 are positioned on a circle concentric to the supporting plate 58. At this time, a projection plane obtained by projecting the three through holes 84 of the supporting plate 58 in the direction of the plane thereof does not overlap with the projection plane obtained by projecting the supporting strips 66a, 66b, 66c in the direction of the plane. In other words, the supporting strips 66a, 66b, 66c are configured not to close all the three through holes 84 of the supporting plate 58.

In this manner, even when the supporting plate 58 having the plurality of through holes 84 is supported by the supporting strips 66, since the supporting strips 66a, 66b, 66c do not close the through holes 84 of the supporting plate 58, air between the substrate and the supporting plate can be released smoothly through the plurality of through holes 84 when placing the substrate, so that slippage of the substrate can be prevented.

The recesses 88 are formed on the upper surface of the supporting strips 66a, 66b arranged on both sides on which the tweezers 32 are inserted. The recesses 88 are formed by thinning the distal end portions of the supporting strips 66a, 66b while leaving the thickness of the root portions thereof corresponding to the tweezers 32, and the thinned portions include positions where the supporting strips 66a, 66b are placed and the positions where the tweezers 32 are inserted. In this manner, since the thickness of the portions of the supporting strips 66a, 66b corresponding to the tweezers 32 can be reduced, the inter-substrate pitch can be reduced.

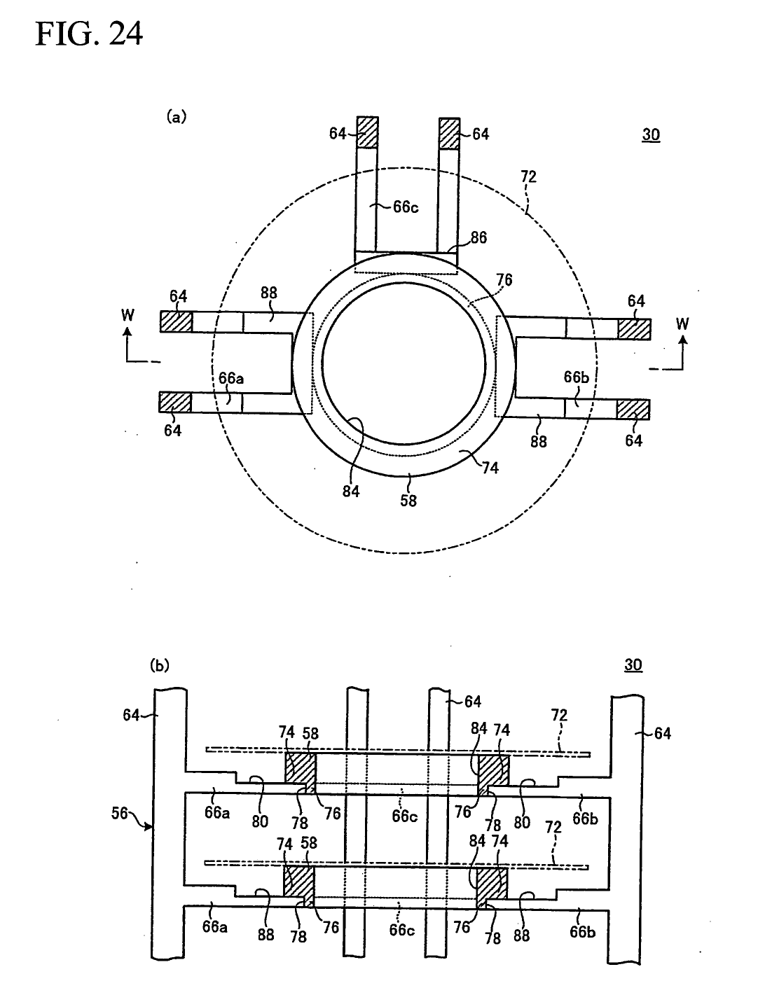

FIG. 24 shows a fifth modification of the third embodiment.

The fourth modification is different from the third embodiment described above in the shape of the supporting plate 58.

The supporting plate 58 includes the thin peripheral portion (outer peripheral portion) 74 and the thick central portion 76, and the engaging groove 78 (fitting portion) is formed on the lower portion (back surface) of the peripheral portion 74. The supporting plate 58 is supported by the supporting strips 66a, 66b, 66c by the engaging groove 78 of the supporting plate 58 fitted to the distal ends of the supporting strips 66a, 66b, 66c.

By the mutual fitting between the supporting strips 66a, 66b, 66c and the engaging groove 78 of the supporting plate 58, the supporting strip 66 can prevent movement (displacement) of the supporting plate 58 with respect to the supporting strips 66a, 66b, 66c in the direction toward the side of the roots of the supporting strips 66a, 66b, 66c. For example, even when a force in the direction of insertion of the substrate is applied to the supporting plate 58, since the engaging groove 78 of the supporting plate 58 is in abutment with the distal end portions of the supporting strips 66a, 66b, 66c, movement (displacement) of the supporting plate 58 with respect to the supporting strips 66a, 66b, 66c can be prevented.

The through hole 84 is provided at the center portion of the supporting plate 58, and is formed into a cylinder being concentric with the substrate 72 and having a cross-section which is a circle concentric with the substrate 72. One end of the through hole 84 opens on the substrate placing surface of the supporting plate 58 and the other end thereof opens on the lower surface of the supporting plate 58 so as to communicate with the outside. At this time the projection plane obtained by projecting the through hole 84 of the supporting plate 58 in the direction of the plane thereof does not overlap with the projection plane obtained by projecting the supporting strip 66 in the direction of the plane. In other words, the supporting strip 66 is configured not to close the through hole 84.

In this manner, since the supporting strip 66 does not close the through hole 84 of the supporting plate 58 even in the case in which the supporting plate 58 having the through hole 84 is supported by the supporting strip 66, air between the substrate and the supporting plate can be released smoothly through the through hole 84 when placing the substrate, so that slippage of the substrate can be prevented.

The recesses 88 are formed on the upper surfaces of the supporting strips 66a, 66b on both sides arranged on the side on which the tweezers 32 are inserted at a position to be opposed to the tweezers 32. The recesses 88 are formed by thinning the distal end portions of the supporting strips 66a, 66b while leaving the thickness of the root portions thereof corresponding to the tweezers 32, and are thinned portions thereof include the position where the supporting plate 58 is placed and the position where the tweezers 32 are inserted. In other words, since the thickness of the portions of the supporting strips 66a, 66b corresponding to the tweezers 32 can be reduced, the inter-substrate pitch can be reduced.

The heat treatment apparatus in the present invention can be applied to the manufacturing process of the substrate.

An example in which the heat treatment apparatus according to the present invention is applied to a step in a SIMOX (Separation by Impanted Oxygen) wafer manufacturing process, which is a type of SOI (Silicon On Insulator) wafer will be described.

In a first step, oxygen ion is injected into a monocrystal silicon wafer with an ion injection apparatus or the like. Subsequently, the wafer having the oxygen ion injected therein is annealed at a temperature higher than 1300° C. to 1400° C., for example, higher than 1350° C. in an atmosphere of Ar, O2 using the heat treatment apparatus according to the above-described embodiment. With such a treatment, a SIMOX wafer on which an SiO2 layer is formed in the interior of the wafer (in which the SiO2 layer is implanted) is manufactured.

In addition to the SIMOX wafer, the heat treatment apparatus according to the present invention can be applied to a step in a hydrogen anneal wafer manufacturing process. In this case, the wafer is annealed at a high temperature higher than 1200° C. in a hydrogen atmosphere using the heat treatment apparatus of the present invention. Accordingly, crystal defect of an wafer surface layer on which an IC (Integrated Circuit) is formed can be reduced, and hence perfectibility of the crystal is enhanced.

In addition to it, it is also possible to apply the heat treatment apparatus according to the present invention to a step in an epitaxial wafer manufacturing process.

Even in a case in which a high-temperature anneal processing is employed as one step in the substrate manufacturing processes as described above, by the use of the heat treatment apparatus according to the present invention, the total thickness of the supporting plate and the supporting strips in a state in which the supporting plate is supported by the supporting strips may be reduced, and hence the inter-substrate pitch can be reduced.

The heat treatment apparatus according to the present invention can be applied to a semiconductor device manufacturing process.

In particular, it is preferable to apply the present invention to heat treatment processes which is performed at a relatively high temperature, for example, thermal oxidization process such as wet oxidization, dry oxidization, hydrogen burning oxidization (pyrogenic oxidization), HCl oxidization, or to thermal diffusion processes for diffusing impurities (dopant) such as boron (B), phosphorus (P), Arcanum (As), antimony (Sb) into a semiconductor thin film.

In the case in which the heat treatment process is performed as one step of the semiconductor device manufacturing process, by using the heat treatment apparatus according to the present invention, the total thickness of the supporting plate and the supporting strips in the state in which the supporting plate is supported by the supporting strips can be reduced and the inter-substrate pitch can be reduced.

### INDUSTRIAL APPLICABILITY

The present invention can be utilized to a heat treatment apparatus for a substrate which is to be heat-treated under a high temperature.

1. A heat treatment apparatus comprising:
a reactor for treating substrates; and
a supporting tool for supporting a plurality of the substrates in a plurality of stages in the reactor;
wherein the supporting tool comprises a plurality of supporting plates that come into contact with the plurality of substrates respectively, and a plurality of supporting strips for supporting the plurality of supporting plates in the plurality of stages, and the supporting plates and the supporting strips overlap at least partly in a direction of the thickness.

2. The heat treatment apparatus according to claim 1, wherein recesses are formed on either one of back surfaces of the supporting plates or upper surfaces of the supporting strips.

3. The heat treatment apparatus according to claim 1, wherein the recesses are formed on the upper surfaces of the supporting strip that come into contact with the back surfaces of the supporting plates.

4. The heat treatment apparatus according to claim 1, further comprising a substrate transfer unit for transferring the substrates to the supporting tool, wherein the substrate transfer unit includes tweezers for putting the substrates, and wherein the supporting strips are formed with recesses on the upper surfaces thereof at least at portions that oppose the tweezers when transferring the substrates.

5. The heat treatment apparatus according to claim 4, wherein the recesses are provided on the supporting strips at least in a range from the portions that opposes the tweezers when transferring the substrates to ends on a side where the supporting plates are supported.

6. The heat treatment apparatus according to claim 1, wherein fitting portion for fitting mutually the supporting plate and the supporting strips is provided at least on one of the supporting plates and the supporting strips.

7. The heat treatment apparatus according to claim 1, wherein the supporting strips are configured to support at least outer peripheral portions of the supporting plates on a substrate insertion side.

8. The heat treatment apparatus according to claim 1, wherein the supporting strip has a skeleton structure, wherein the supporting plate comprises at least one through hole, the supporting strips are configured so as not to overlap at least one through hole.

9. The heat treatment apparatus according to claim 8, wherein the supporting plate comprises one through hole at a center thereof, and the supporting strips are configured to support an outer portion of the through hole.

10. The heat treatment apparatus according to claim 1, wherein the supporting tool further comprises a plurality of pillars, the supporting strips are formed integrally with the pillars so as to connect the plurality of pillars, and the supporting strips and the pillars are formed of SiC impregnated with Si.

11. A heat treating apparatus comprising:
a reactor for treating substrates; and
a supporting tool for supporting the substrates in the reactor,
wherein the supporting tool includes a supporting plate that comes into contact with the substrate, and a supporting strip for supporting the supporting plate, and wherein a fitting portion for fitting mutually the supporting plates and the supporting strips is provided at least on one of the supporting plate and the supporting strip.

12. A heat treatment apparatus comprising:
a reactor for treating a substrate; and
a supporting tool for supporting the substrates in the reactor,
wherein the supporting tool comprises a supporting plate that comes into contact with the substrate, and a supporting strip for supporting the supporting plate, and wherein the supporting strip is configured to support at least an outer peripheral portion of the supporting plate on a substrate insertion side.

13. A heat treatment apparatus comprising:
a reactor for treating a substrate; and
a supporting tool for supporting the substrate in the reactor,
wherein the supporting tool includes a supporting plate that comes into contact with the substrate, and a supporting strip for supporting the supporting plate, wherein the supporting strip has a skeleton structure, wherein the supporting plate comprises at least one through hole, and the supporting strips are configured so as not to overlap at least one through hole.

14. A method of manufacturing a substrate comprising a step of:
supporting a plurality of the substrates in a plurality of stages with a supporting tool including a plurality of supporting plates that come into contact with the plurality of substrates respectively, and a plurality of supporting strips for supporting the plurality of supporting plates in the plurality of stages and being configured in such a manner that the supporting plates and the supporting strips overlap at least partly in a direction of thickness,
carrying the plurality of substrates supported by the supporting tool into a reactor,
heat-treating the plurality of substrates supported by the supporting tool in the reactor,
carrying out the plurality of substrates supported by the supporting tool from the reactor after having heat-treated.
